(19) United States
(12) Patent Application Publication
(10) Pub. No.: US 2012/0307561 A1
(43) Pub. Date: Dec. 6, 2012

(54) NON-VOLATILE MEMORY DEVICE AND METHOD CONTROLLING DUMMY WORD LINE VOLTAGE ACCORDING TO LOCATION OF SELECTED WORD LINE

(75) Inventors: Sang-Hyun Joo, Hwaseong-si (KR); Ki Hwan Choi, Seongnam-si (KR); Moo Sung Kim, Yongin-si (KR)

(73) Assignee: SAMSUNG ELECTRONICS CO., LTD., Suwon-si (KR)

(21) Appl. No.: 13/327,415

(22) Filed: Dec. 15, 2011

(30) Foreign Application Priority Data
Jun. 3, 2011 (KR) 10-2011-0054190

(51) Int. Cl. G11C 16/10; G06F 12/16; G11C 16/04

(52) U.S. Cl. 365/185.17; 365/185.18; 711/114; 711/E12.103

(57) ABSTRACT

A non-volatile memory device includes access circuitry that selects a word line during an operation, applies a selected word line voltage to the selected word line, applies a non-selected word line voltage to non-selected word lines among the word lines, and applies a dummy word line voltage to the dummy word line. The dummy word line voltage is a first dummy word line voltage when the selected word line is not adjacent to the dummy word line and a second dummy word line voltage different from the first dummy word line voltage when the selected word line is adjacent to the dummy word line.

### CROSS-REFERENCE TO RELATED APPLICATIONS

This application claims priority under 35 U.S.C. §119(a) from Korean Patent Application No. 10-2011-0054190 filed on Jun. 3, 2011, the subject matter of which is hereby incorporated by reference.

### BACKGROUND OF THE INVENTION

The present inventive concept relates to non-volatile memory devices, non-volatile memory cell arrays, systems incorporating non-volatile memory devices, and methods of operating same. More particularly, the inventive concept relates to non-volatile memory devices and non-volatile memory cell arrays including one or more dummy word lines and methods of operating same, as well as systems including such non-volatile memory devices.

Non-volatile memory has become a mainstay component in digital systems and consumer electronics. The term “non-volatile memory” encompasses a broad range of data storage devices capable of retaining store data in the absence of applied power. There are different types of non-volatile memory. One type is the Electrically Erasable Programmable Read Only Memory (EEPROM). So-called “flash memory” is a particular type of EEPROM and has become a particularly important form of non-volatile memory. Contemporary flash memory includes NOR flash memory and NAND flash memory that are distinguished by respective arrangements of access logic.

NAND flash memory may be configured to provide an array of non-volatile memory cells having very high integration density. Among other features associated with the NAND flash memory, this high integration density is enabled by arrangements of NAND flash memory cells in “string” structures. A NAND string is essentially a plurality of NAND flash memory cells connected in series. Usually, a string of NAND flash memory cells is disposed between a string selection transistor connected to a string selection line and a ground selection transistor connected to a ground selection line.

NAND flash memory enjoys many performance and implementation advantages over types of non-volatile and volatile memory. Yet, NAND flash memory is not without its own design considerations. For example, during certain program-inhibit functions, gate induced drain leakage (GIDL) easily occurs in memory cells adjacent to the string selection line and the ground selection line due to the difference between a high voltage on the boosted channel and a low voltage on the gate of the string selection line or the ground selection line. GIDL current typically increases as the voltage difference between the channel of a memory cell and the gate of the string selection line or the ground selection line increases. GIDL current increases the likelihood of hot carrier injection (HCI) disturbance in memory cells adjacent to the string selection line and the ground selection line. Such disturbance leads to a decreased read margin and may deteriorate the overall operating characteristics of a non-volatile memory device.

### SUMMARY OF THE INVENTION

Certain embodiments of the inventive concept provide non-volatile memory devices including flash memory devices, 2D and 3D memory cell arrays including 2D and 3D flash memory cell arrays, related methods of controlling the operation of non-volatile memory devices and memory cell arrays, and systems incorporating non-volatile memory devices. The embodiments intelligently adapt control voltages applied to 2D and 3D memory cell arrays including one or more dummy word lines. Certain dispositional relationships (e.g., dispositional relationship(s) of the dummy word lines within a plurality of word lines, or dispositional relationship(s) between a dummy word line and a selected word line within the plurality of word lines) may be used to determine the applied characteristics (e.g., level, waveform, timing) of certain control voltages (e.g., read voltages, program voltages, erase voltages, dummy word line voltages, main word line voltages, bit line voltages) to a memory cell array. As a result, the incidence of disturbance in constituent memory cells may be markedly reduced. Consequently, a decrease in a read margin due to the disturbance can be suppressed, and furthermore, the operating characteristics of the non-volatile memory device can be improved.

One embodiment is directed to a non-volatile memory device, comprising; an array of nonvolatile memory cells arranged in relation to word lines including a dummy word line, and access circuitry that selects during an operation a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a non-volatile memory device, comprising; a vertical memory cell array including a plurality of non-volatile memory cells arranged in a plurality of memory cell array layers stacked in a first direction, and words lines that extend in a second direction across the plurality of memory cell array layers and include a dummy word line, and access circuitry that selects during an operation a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage when the selected word line is adjacent to the dummy word line.

Another embodiment is directed to a non-volatile memory device, comprising; a vertical memory cell array including a plurality of non-volatile memory cells arranged in a plurality of memory cell array layers stacked in a first direction, and words lines that extend in a second direction across the plurality of memory cell array layers and include a plurality of dummy word lines, and access circuitry that selects during an operation a word line among the word lines in response to a received address, applies a selected word line voltage to the selected word line, applies a non-selected word line voltage to non-selected word lines among the word lines, and respectively applies one of a plurality of dummy word line voltages to each one of the plurality of dummy word lines, wherein the plurality of dummy word line voltages comprises; a first dummy word line voltage applied to a respective dummy word line when the selected word line is not adjacent to the respective dummy word line, and a second dummy word line voltage applied to the respective dummy word line when the selected word line is adjacent to the respective dummy word line.

Another embodiment is directed to a non-volatile memory device, comprising; a vertical memory cell array including a plurality of non-volatile memory cells arranged in a plurality of memory cell array layers stacked in a first direction, and words lines that extend in a second direction across the plurality of memory cell array layers and include a plurality of dummy word lines, and access circuitry that selects during an operation a word line among the word lines in response to a received address, applies a selected word line voltage to the selected word line, applies a non-selected word line voltage to non-selected word lines among the word lines, and respectively applies one of a plurality of dummy word line voltages to each one of the plurality of dummy word lines, wherein the plurality of dummy word line voltages comprises; a first dummy word line voltage applied to a respective dummy word line when the selected word line is not adjacent to the respective dummy word line, and a second dummy word line voltage applied to the respective dummy word line when the selected word line is adjacent to the respective dummy word line. At least one of the first dummy word line voltage has a different waveform than that of the second dummy word line voltage, and the first dummy word line voltage has a different level than that of the second dummy word line voltage, and the plurality of dummy word lines comprises at least one terminal dummy word line and at least one intermediate dummy word line. Each one of the plurality of nonvolatile memory cells is a NAND flash memory cell, and the plurality of nonvolatile memory cells is further arranged in a plurality of NAND memory cell strings that respectively extend in the first direction through the stacked plurality of memory cell layers, and each one of the plurality of NAND memory cell strings comprises; a string selection transistor coupled to a string selection line, a ground selection transistor coupled to a ground selection line, a first set of NAND flash memory cells connected in series between the string selection transistor and the intermediate dummy word line and respectively coupled to a first set of the word lines, and a second set of NAND flash memory cells connected in series between the intermediate dummy word line and the ground selection transistor, and respectively coupled to a second set of the word lines.

Another embodiment is directed to a system comprising; a memory controller configured to control operation of a non-volatile memory device, wherein the non-volatile memory device comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a memory card system, comprising; an interface operatively connecting the memory card system with a host to receive input data from the host and communicate output data to the host, a memory controller configured to receive the input data from the interface, store the input data in a non-volatile memory device, receive the output data from the nonvolatile memory device, and communicate the output data to the host, wherein the non-volatile memory device comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a Solid State Drive (SSD), comprising; a memory controller configured to control operation of a plurality of non-volatile memory devices via a plurality of channels, wherein each one of the plurality of non-volatile memory devices comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a redundant array of independent disks (RAID) system, comprising; a RAID controller connected to a plurality of memory systems via respective channels, wherein each one of the plurality of memory systems comprises a memory controller configured to control operation of a plurality of non-volatile memory devices, and wherein each one of the plurality of non-volatile memory devices comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a method of operating a nonvolatile memory device, comprising; receiving an address associated with an operation to be executed by the nonvolatile memory device, and in response to the address, selecting a word line among word lines of the nonvolatile memory device, applying a selected word line voltage to the selected word line, applying a non-selected word line voltage to non-selected word lines among the word lines, and applying a dummy word line voltage to a dummy word line among the word lines, wherein the dummy word line voltage is a first dummy word line voltage when the selected word line is not adjacent to the dummy word line and a second dummy word line voltage different from the first dummy word line voltage when the selected word line is adjacent to the dummy word line.

Another embodiment is directed to a method of operating a memory system comprising a memory controller and a nonvolatile memory device, the nonvolatile memory device including word lines and a dummy word line, and the method comprising; communicating a command and an address from the memory controller to the nonvolatile memory device, wherein the address selects a word line among the word lines, determining whether the selected word line is adjacent to the dummy word line, and upon determining that the selected word line is adjacent to the dummy word line applying a first dummy word line voltage to the dummy word line, else applying a second dummy word line voltage different from the first dummy word line voltage to the dummy word line.

Another embodiment is directed to a non-volatile memory device, comprising; an array of nonvolatile memory cells arranged in relation to word lines including a dummy word line, and access circuitry that during an operation selects a word line among the word lines in response to a received address, applies a selected word line voltage to the selected word line, and applies a non-selected word line voltage to non-selected word lines among the word lines, wherein the access circuitry comprises dummy word line control logic that during the operation applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

### BRIEF DESCRIPTION OF THE DRAWINGS

The above and other features and advantages of the inventive concept will become more apparent upon consideration of certain exemplary embodiments thereof with reference to the attached drawings in which:

FIG. 1 is a block diagram of a non-volatile memory device according to an embodiment of the inventive concept;

FIG. 2A further illustrates one possible horizontal memory cell array for the non-volatile memory device of FIG. 1;

FIG. 2B further illustrates one possible vertical memory cell array for the non-volatile memory device of FIG. 1;

FIG. 3A is a block diagram of a dummy word line control logic and a dummy word line voltage generator according to an embodiment of the inventive concept;

FIG. 3B is a block diagram of a dummy word line control logic and a dummy word line voltage generator according to another embodiment of the inventive concept;

FIG. 3C is a block diagram of a dummy word line control logic and a dummy word line voltage generator according to yet another embodiment of the inventive concept;

FIG. 4 is a flowchart summarizing one possible method of operating the non-volatile memory device of FIG. 1;

FIG. 5 is a diagram explaining the definition and provision of a dummy word line according to a typical program operation;

FIGS. 6 and 7 are diagrams explaining the definition and provision of a dummy word line voltage according to certain embodiment of the inventive concept;

FIG. 8, inclusive of FIGS. 8A through 8D, and FIG. 9, inclusive of FIGS. 9A through 9D are diagrams that further explain the definition and provision of a dummy word line voltage according to a typical read operation;

FIG. 10, inclusive of FIGS. 10A through 10D are diagrams that further explain the definition and provision of a dummy word line voltage according to an embodiment of the inventive concept;

FIG. 11 is a graph showing an overshoot occurring in relation to typical bias conditions of a dummy word line;

FIG. 12 is a graph showing changes in the waveform of the voltage of a dummy word line depending on a selected word line according to an embodiment of the inventive concept;

FIGS. 13A and 13B are diagrams explaining a method of changing the level and the waveform of the voltage of a dummy word line depending on a selected word line according to some embodiments of the present inventive concept;

FIGS. 14 through 17 are diagrams showing examples of controlling the voltage of a dummy word line according to the location of a selected word line in a three-dimensional NAND memory device according to embodiments of the inventive concept;

FIGS. 18A and 18B are diagrams showing different examples of controlling the voltage of a dummy word line according to the location of a selected word line according to embodiments of the inventive concept.

FIG. 19 is a block diagram of a memory system including the non-volatile memory device of FIG. 1 according to an embodiment of the inventive concept;

FIG. 20 is a block diagram of a memory system including the non-volatile memory device of FIG. 1 according to another embodiment of the inventive concept;

FIG. 21 is a block diagram of a memory system including the non-volatile memory device of FIG. 1 according to yet another embodiment of the inventive concept;

FIG. 22 is a block diagram of a memory system including the non-volatile memory device of FIG. 1 according to still another embodiment of the inventive concept;

FIG. 23 is a block diagram of a memory system including the non-volatile memory device of FIG. 1 according to yet another embodiment of the inventive concept;

FIG. 24 is a block diagram of a memory system including the non-volatile memory device of FIG. 1 according to still another embodiment of the inventive concept; and

FIG. 25 is a block diagram of a data processor including the memory system of FIG. 24.

### DETAILED DESCRIPTION

Embodiments of the inventive concept will now be described in some additional detail with reference to the accompanying drawings. The inventive concept may, however, be embodied in many different forms and should not be construed as being limited to only the illustrated embodiments. Rather, these embodiments are provided so that this disclosure will be thorough and complete, and will fully convey the scope of the inventive concept to those skilled in the art. Throughout the written description and drawings, like numbers and labels are used to denote like or similar elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Recognizing the growing impact of non-volatile memory device performance on incorporating host device performance, non-volatile memory devices are sought that retain or improve read margins under increasingly challenging operating conditions. Such operating conditions may be generally characterized as including one or more demands for reduced power consumption, higher operating frequency, expanded data bandwidth, and greater error detection and correction capabilities. Additionally, emerging memory systems are demanding such increased data storage density and capabilities that legacy two-dimension (2D) or horizontal memory arrays are proving inadequate. Thus, many emerging memory systems are incorporating three-dimensional (3D) or vertical memory arrays. A vertical memory array is any configuration where at least one semiconductor layer incorporating memory cells is vertically stacked on top of another semiconductor layer incorporating memory cells. In the embodiments described hereafter, certain horizontal (2D) and vertical (3D) memory array structures will be described. Those skilled in the art will recognize that the features of memory arrays described herein as horizontal configurations may be extended to similarly arranged vertical memory arrays.

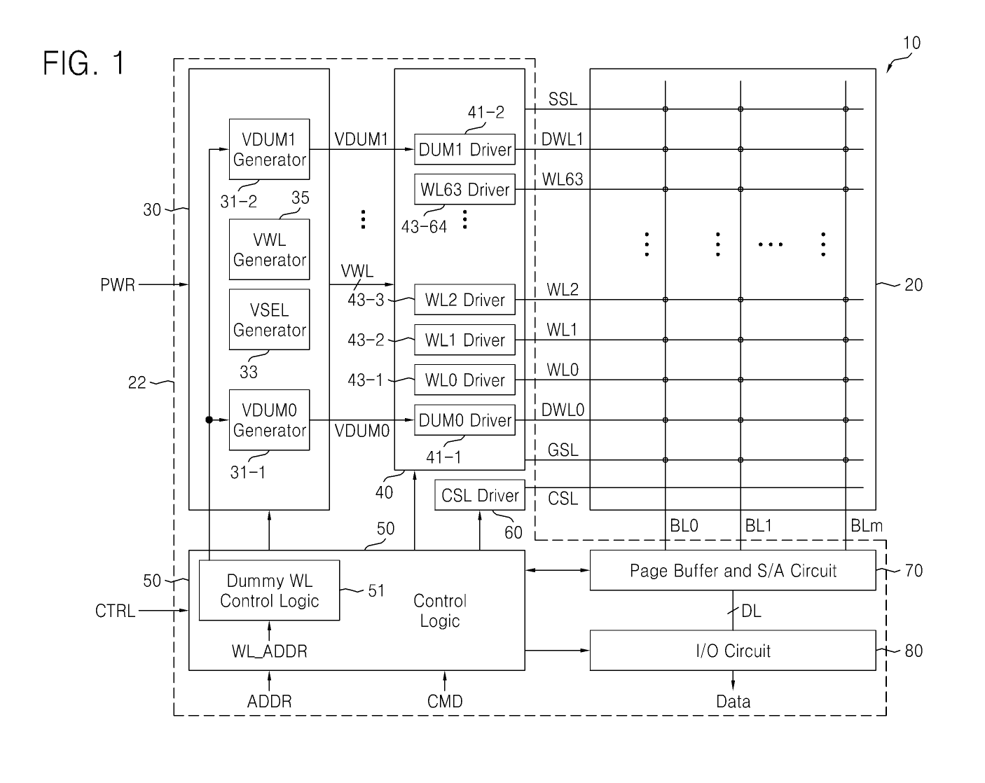

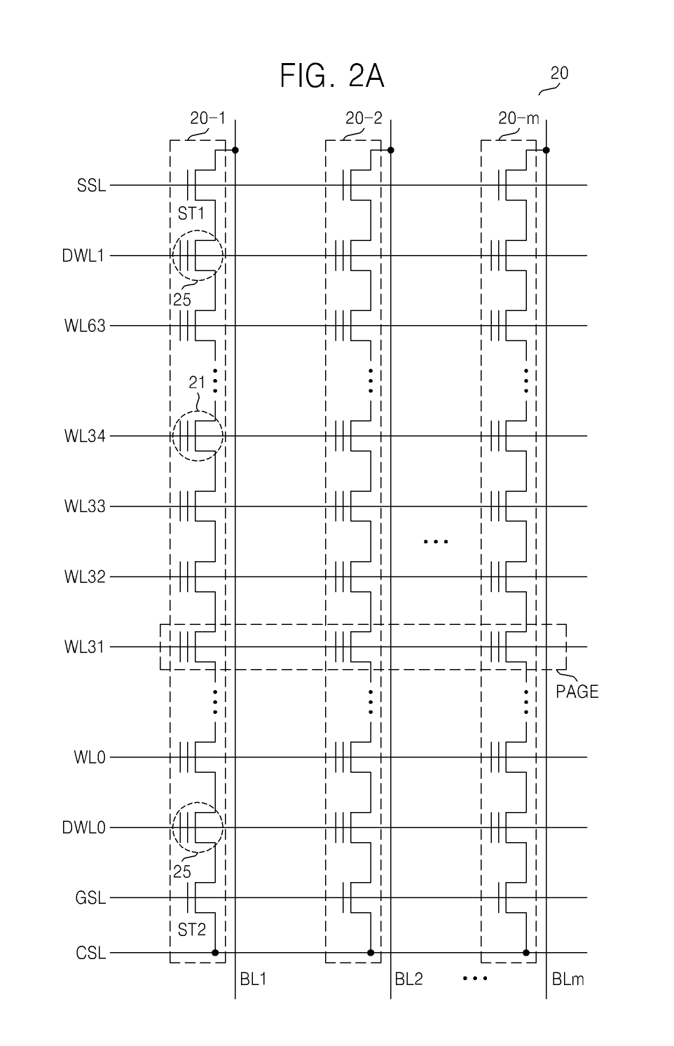

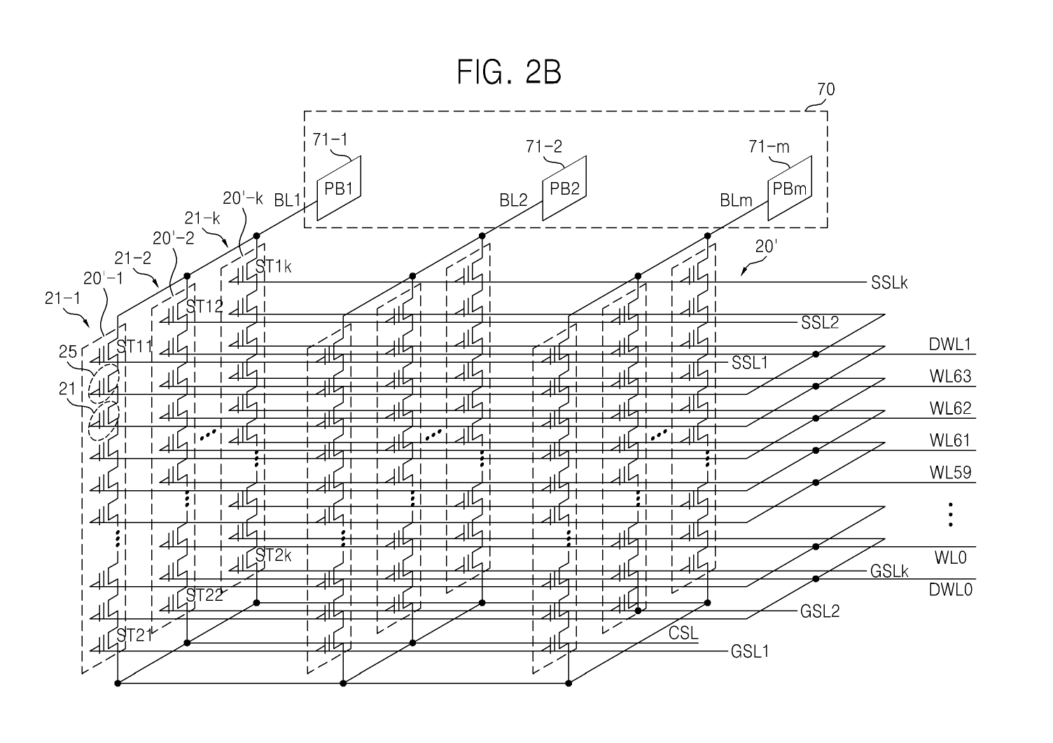

FIG. 1 is a block diagram illustrating in relevant portion a non-volatile memory device 10 according to certain embodiments of the inventive concept. FIG. 2A further illustrates a non-volatile memory cell array 20 in relevant portion as a horizontal memory cell array, whereas FIG. 2B further illustrates a memory cell array 20′ as a vertical memory cell array. Either one of non-volatile memory cell array 20 or non-volatile memory cell array 20′ may be incorporated into the non-volatile memory device 10 of FIG. 1.

It should be noted at this point that the illustrated embodiments assume the use of NAND flash memory cells within the constituent memory cell arrays. However, those skilled in the art will recognize that the scope of the inventive concept is not limited to only memory cell arrays including NAND type flash memory cells.

Referring to FIGS. 1 and 2A, the non-volatile memory device 10 comprises the memory cell array 20 and an access circuit 22. Given the NAND flash memory working assumption for the illustrated embodiments, program and read operations within the non-volatile memory device 10 are performed on a page by page basis (i.e., in page units) while erase operations within the non-volatile memory device 10 are performed on a block by block basis (i.e., in block units), wherein each block includes a plurality of pages.

As shown in FIG. 2A, the memory cell array 20 includes a plurality of NAND memory cell strings 20-1, 20-2, . . . , 20-m, where “m” is a natural number. Each of the NAND memory cell strings 20-1 through 20-m includes a plurality of non-volatile memory cells 21 and dummy cells 25 connected in series. The NAND memory cell strings 20-1 through 20-m are principally arranged in a single “horizontal” plane defined by two (X and Y) dimensions.

The NAND memory cell string 20-1 includes the plurality of non-volatile memory cells 21 and dummy cells 25, which are connected in series between a string selection transistor ST1 (or a first selection transistor) connected to a bit line BL1 and a ground selection transistor ST2 (or a second selection transistor) connected to a common source line CSL. The gate of the first selection transistor ST1 is connected to a string selection line SSL. The gates of the plurality of non-volatile memory cells 21 are respectively connected to a plurality of word lines WL0 through WL63. The gate of the second selection transistor ST2 is connected to a ground selection line GSL. The gates of the respective dummy cells 25 are respectively connected to dummy word lines DWL0 and DWL1.

In the illustrated embodiment of FIG. 2A, the NAND memory cell strings 20-1 through 20-m have substantially the same structure, and although 64 word lines WL0 through WL63 and two dummy word lines DWL0 and DWL1 are illustrated in FIGS. 1, 2A and 2B, other embodiments of the inventive concept are not restricted to this particular number and arrangement of word lines and dummy word lines. For example, the dummy word lines DWL0 and DWL1 illustrated in the FIGS. 1, 2A and 2B are disposed at opposing ends of a group of the word lines WL0 through WL63 (i.e., directly and respectively adjacent to the string selection line SSL and the ground selection line GSL). However, other embodiments of the inventive concept may incorporate dummy word lines otherwise disposed in relation to selection lines and groupings of word lines.

Each of the non-volatile memory cells 21 included in each of the NAND memory cell strings 20-1 through 20-m may be implemented using multi-level flash memory cells (MLC) and/or single-level flash memory cells (SLC).

As illustrated in FIG. 2B, NAND memory cell strings 20′4, 20′-2, . . . , 20′-k, where “k” is a natural number, may be arranged in different and multiple planes defined by three (X, Y and Z) dimensions. That is, a vertical memory array may be configured by arranging in a “vertical” stack a plurality of “horizontal” memory arrays, (e.g., NAND memory cell strings 20′-1 through 20′-k). In this context, those skilled in the art will recognize that the terms “vertical” and “horizontal” define relative and arbitrary geometric relationships. Many different fabrication and assembly techniques may be used to implement a vertical memory array. For example, the plurality of material layers 21-1 through 21-k respectively implementing horizontal the NAND memory cell strings 20′-1 through 20′-k may be implemented as a wafer stack, a chip stack, or a cell stack. The material layers 21-1 through 21-k may be “stacked connected” one to another using one or more elements (and related fabrication techniques), such as through-silicon vias (TSV), conductive bumps, wire bonding, distribution wiring, etc.

The NAND memory cell strings 20′-1 through 20′-k of FIG. 2B may be configured to share, and operate in response to an access circuit similar to the access circuit 22 of FIG. 1A. This type of access circuit is capable of selectively accessing the memory cells in the vertical memory array using a variety of operations, such as program, read, and erase operations.

Similar to the horizontal memory cell array of FIG. 2A, the first NAND memory cell string 20′-1 of the first layer 21-1 of FIG. 2B includes a plurality of non-volatile memory cells (e.g., NAND flash memory cells) 21 and dummy cells 25 connected in series between first and second selection transistors ST11 and ST21. The second NAND memory cell string 20′-2 of the second layer 21-2 includes a plurality of non-volatile memory cells 21 and dummy cells 25 connected in series between first and second selection transistors ST12 and ST22. The k-th NAND memory cell string 20′-k of the k-th layer 21-k includes a plurality of non-volatile memory cells 21 and dummy cells 25 connected in series between first and second selection transistors ST1k and ST2k.

As shown in FIG. 2B, the NAND memory cell strings 20′-1 through 20′-k may share (i.e., be commonly connected to) the plurality of word lines WL0 through WL63 (or a subset thereof), at least one of a plurality of bit lines BL1 through BLm, and one or more control signal lines (e.g., common source line CSL). In other words, NAND memory cell strings at corresponding positions in the respective material layers 21-1 through 21-k may be connected to a corresponding one of a plurality of page buffers 71-1 through 71-m included within a page buffer and sense amplifier (S/A) block 70.

Referring to FIG. 1, the access circuit 22 is configured to selectively access one or more memory cells arranged within the memory cell array 20 using such conventionally understood operations a program operation, a read operation, and an erase operation. Such operations may be executed in response to a command (or collection of commands) and related addresses externally provided from a source, such as (e.g.,) a memory controller (not shown). As is conventionally understood, the program operations executed by access circuit 22 may include a program verify operation, and the erase operation may include an erase verify operation.

Referring now to FIGS. 1 and 2A, the access circuit 22 is assumed to receive an externally provided program command, related addresses (i.e., a set or range of addresses), and “write data” (e.g., a page of write data) to be programmed to the memory cell array 20. In response to the program command, the access circuit 22 generates the control signals necessary to cause the programming (or storing) of the given write data to the memory cell array. Assuming a simple example wherein a particular page of write data is defined in relation to a particular word line (e.g., WL31), a corresponding address is applied to “select” the particular word line from among the plurality of word lines WL0 through WL63 connected to a NAND memory cell string (e.g., 20-1). Thus, in response to the program command and associated address, the one particular word line becomes, as least during the constituent program operation, a “selected word line” while the other word lines remain “non-selected word lines.” Hence, a selected word line is a word line associated with one or more memory cells receiving write data during a program operation, and non-selected word lines are word lines not associated with the memory cells receiving the write data.

Similar distinctions between word lines may be made during a read operation. Thus, in response to a read command and associated address, the one particular word line becomes, as least during the constituent read operation, a “selected word line” while the other word lines remain “non-selected word lines.” Hence, a selected word line is a word line associated with one or more memory cells from which “read data” is retrieved during a read operation, and non-selected word lines are word lines not associated with the memory cells from which read data is retrieved.

In addition to the definition and generation of other control signals (e.g., voltage(s) and/or current(s)) applied to the plurality of word lines, the plurality of bit lines, and/or one or more control lines (e.g., the CSL, SSL, GSL), the access circuit 22 defines and generates certain control signals applied to the dummy word lines. More particularly, the definition, generation and application of dummy word line signals (e.g., voltages) by access circuitry designed and operated in accordance with embodiments of the inventive concept is controlled, at least in part, by the location of a selected word line among the plurality of word lines—during the current operation—in relation to the location of one or more dummy word lines among the plurality of word lines.

In one example consistent with embodiments of the inventive concept, when a selected word line during an operation is “adjacent to” (i.e., immediately disposed on either side of the dummy word line without another word line intervening) a dummy word line within an arranged plurality of word lines, then a first dummy word line voltage applied to the dummy word line during the operation will be different from a second dummy word line applied to the dummy word line during a similar operation when the selected word line is not adjacent to the dummy word line. For instance, a read voltage applied to a dummy word line will be changed during a read operation depending on whether or not a word line selected by the read operation is adjacent to a dummy word line in a memory block. Similarly, the voltage applied to the dummy word line will be changed during a program operation depending on whether or not a word line selected by the program operation is adjacent to a dummy word line in the memory block.

This approach to controlling the execution of operations directed to data stored in (or to be stored in) a memory cell array will be described in some additional detail with reference to the embodiment illustrated in FIGS. 1 and 2A. In FIG. 1, the exemplary access circuit 22 comprises a voltage supply circuit 30, a row driver 40, a control logic 50, a common selection line (CSL) driver 60, the page buffer and S/A circuit 70, and an input/output (I/O) circuit 80.

The voltage supply circuit 30 generates and provides through the row driver 40 certain control voltage(s) that are necessary to cause the execution of various operations. These control voltages include certain voltages applied on a row-wise basis by the row driver 40 and that vary in level and/or activation/deactivation timing by operation. For instance, the voltage supply circuit 30 may generate a program voltage during a program operation, an erase voltage during an erase operation, and a read voltage during a read operation. It should be noted that some embodiments of the inventive concept contemplate a program operation applying a program voltage generated according to an incremental step pulse program (ISPP) scheme. Other embodiments of the inventive concept contemplate an erase voltage generated according to an incremental step pulse erase (ISPE) scheme.

The voltage supply circuit 30 illustrated in FIG. 2A includes first and second dummy word line voltage generators 31-1 and 31-2, a selection voltage generator 33, and a main word line voltage generator 35. The first and second dummy word line voltage generators 31-1 and 31-2 respectively generate and provide first and second dummy word line voltages VDUM0 and VDUM1 to the first and second dummy word lines DWL0 and DWL1. The selection voltage generator 33 generates voltages applied to the string selection line SSL and the ground selection line GSL. The main word line voltage generator 35 generates various word line voltages VWL applied to the plurality of word lines WL0 through WL63. In the foregoing context, it should be noted that the various generators within the voltage supply circuit 30 may be implemented using one or more voltage generator circuits. Hence, the signal-specific descriptions of generators given above are provided to set forth a functional or operative distinctions, rather than distinctions necessarily associated with separate circuitry. Indeed, many embodiments of the inventive concept will seek to provide the necessary control voltages using a minimum of hardware resources to reduce the resulting size of the constituent non-volatile memory device.

The control logic 50 controls the overall operation of the access circuit 22. And in the illustrated embodiment of FIG. 1, the control logic 50 may be used to control the operation of the dummy word line voltage generators 31-1 and 31-2. For example, particular logic hardware (and/or related software routine(s)) may be used to control the dummy word line voltage generators 31-1 and 31-2. However, specifically implemented within the control logic 50, this hardware, firmware, and/or software will be referred to as dummy word line control logic 51. Several examples of possible structure(s) and functional operation for the dummy word line control logic 51 will be described hereafter.

The page buffer and S/A circuit 70 may include a plurality of the page buffers 71-1 through 71-m, as illustrated in FIG. 2B. The page buffers 71-1 through 71-m may be respectively connected to a plurality of bit lines BL1 through BLm. Each of the page buffers 71-1 through 71-m may operate as a driver during a program operation to program write data to the memory cell array 20′ under the control of the control logic 50, and also operate as a sense amplifier (S/A) during a read operation or a verify operation to senses and amplify a bit line voltage level under the control of the control logic 50.

The I/O circuit 80 may be selectively configured to communicate externally provided write data to the page buffer and S/A circuit 70, or communicate read data provided by the page buffer and S/A circuit 70 to an external circuit through a plurality of I/O pins or a data bus. The I/O pins associated with the I/O circuit 80 may be used to receive address information (e.g., program addresses, read addresses, or erase addresses), command information (e.g., a program command, read command, or erase command); and/or write data associated with the program command. Various addresses may include column addresses and/or row addresses.

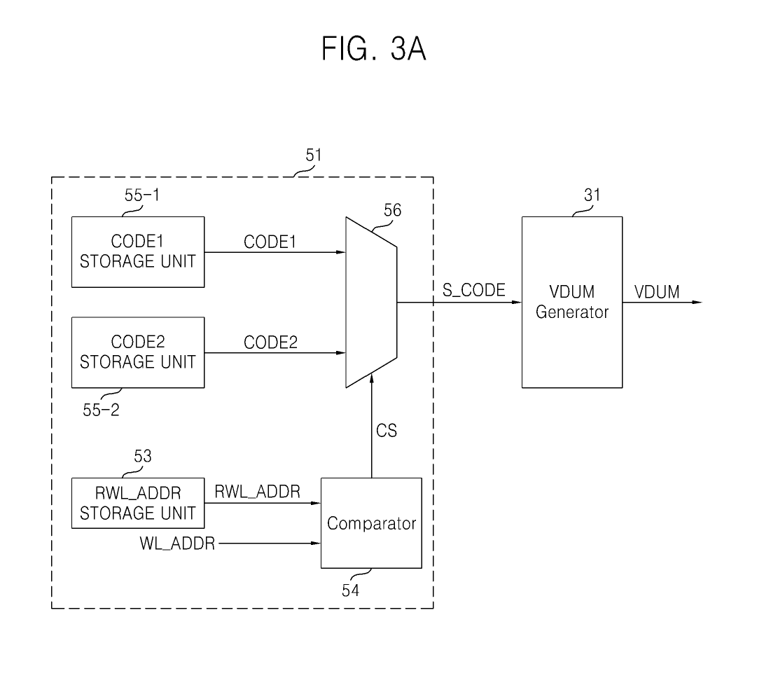

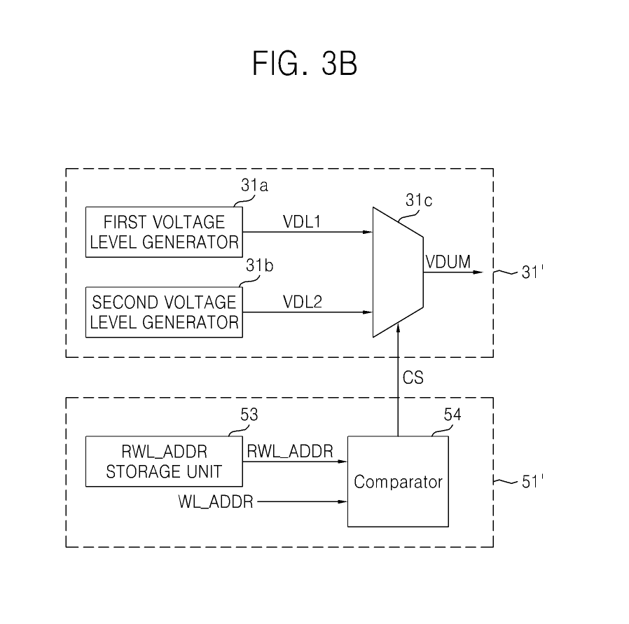

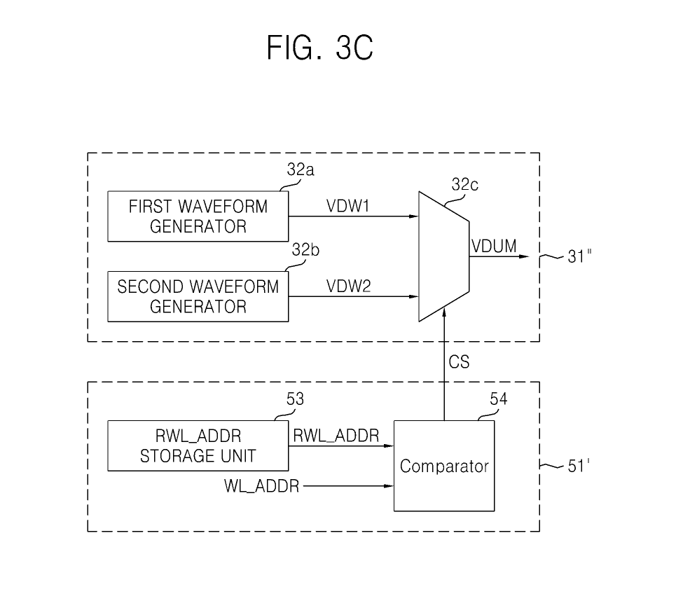

FIGS. 3A through 3C are block diagrams further illustrating several possible implementation examples for the dummy word line control logic 50 and dummy word line voltage generator 31 of FIG. 1. FIG. 3A is a block diagram of the dummy word line control logic 51 and a dummy word line voltage generator 31 according to one embodiment of the inventive concept. Referring to FIG. 3A, the dummy word line control logic 51 comprises a reference address storage unit 53, a comparator 54, first and second code storage units 55-1 and 55-2, and a selector 56.

The reference address storage unit 53 stores a reference address RWL_ADDR. The first and second code storage units 55-1 and 55-2 respectively store first and second codes CODE1 and CODE2 previously received. At least one among the reference address RWL_ADDR and the first and second codes CODE1 and CODE2 may be implemented as a register. The register may be implemented using a static random access memory (SRAM) or an electronic fuse register, but embodiments of the inventive concept are not restricted thereto.

The at least one among the reference address RWL_ADDR and the first and second codes CODE1 and CODE2 may be stored as a hard-wired value. For instance, when the reference address RWL_ADDR is stored as a hard-wired value of “101”, a value of “1” may be implemented by connection to a power supply voltage and a value of “0” may be implemented by connection to ground. However, the reference address storage unit 53 and the first and second code storage units 55-1 and 55-2 may be otherwise implemented.

The reference address RWL_ADDR is an address that may be used to determine whether a selected word line is adjacent to a dummy word line. Hence, multiple reference addresses may be used to respectively indicate corresponding dummy word lines.

The comparator 54 compares a selected address WL_ADDR with the reference address RWL_ADDR and outputs a comparison signal CS. The selected address WL_ADDR is an address corresponding to a word line selected during an operation (e.g., a program or read operation) and may be externally provided or generated in response to an input address.

The comparator 54 may output the comparison signal CS at a first logic level (e.g., “0”) when the selected address WL_ADDR is less than or equal to the reference address RWL_ADDR and the comparison signal CS at a second logic level (e.g., “1”) when the selected address WL_ADDR is greater than the reference address RWL_ADDR. As an alternative, the comparator 54 may output the comparison signal CS at the first logic level (e.g., “0”) when the selected address WL_ADDR is greater than or equal to the reference address RWL_ADDR and the comparison signal CS at the second logic level (e.g., “1”) when the selected address WL_ADDR is less than the reference address RWL_ADDR. Alternatively, the comparator 54 may output the comparison signal CS at the first logic level (e.g., “0”) when the selected address WL_ADDR is within a predetermined range from the reference address RWL_ADDR and the comparison signal CS at the second logic level (e.g., “1”) otherwise.

The selector 56 selects and outputs either of the first and second codes CODE1 and CODE2 as a selection code S_CODE in response to the comparison signal CS.

In the embodiment illustrated in FIG. 3A, the dummy word line voltage generator 31 generates a dummy word line voltage VDUM at a level corresponding to the selection code S_CODE. The dummy word line voltage generator 31 may be a voltage generator that generates a voltage at a different level depending on a code value. Accordingly, the dummy word line voltage generator 31 may generate a word line voltage at a different level depending on the selection code S_CODE, but the present inventive concept is not restricted to the current embodiments. Alternatively, the dummy word line voltage generator 31 may generate a word line voltage having a different waveform depending on the selection code S_CODE.

FIG. 3B is a block diagram of a dummy word line control logic 51′ and a dummy word line voltage generator 31′ according to another embodiment of the inventive concept. The dummy word line control logic 51′ includes the reference address storage unit 53 and the comparator 54. The reference address storage unit 53 and comparator 54 of FIG. 3B may perform the same functions described above in relation to the embodiment illustrated in FIG. 3A.

The dummy word line voltage generator 31′ includes first and second voltage level generators 31a and 31b and a selector 31c. The first and second voltage level generators 31a and 31b generate first and second voltage levels VDL1 and VDL2, respectively. The selector 31c selects and outputs either of the first and second voltage levels VDL1 and VDL2 as the dummy word line voltage VDUM in response to the comparison signal CS.

FIG. 3C is a block diagram of a dummy word line control logic 51′ and a dummy word line voltage generator 31″ according to another embodiment of the inventive concept. To avoid undue descriptive redundancy, only differences between the embodiments illustrated in FIGS. 3B and 3C will be described.

The dummy word line voltage generator 31″ includes first and second waveform generators 32a and 32b instead of the first and second voltage level generators 31a and 31b illustrated in FIG. 3B. In other words, while the dummy word line voltage generator 31′ illustrated in FIG. 3B selects and outputs either of different voltage levels as the dummy word line voltage VDUM in response to the comparison signal CS, the dummy word line voltage generator 31″ illustrated in FIG. 3C selects and outputs either of different waveforms as the dummy word line voltage VDUM in response to the comparison signal CS.

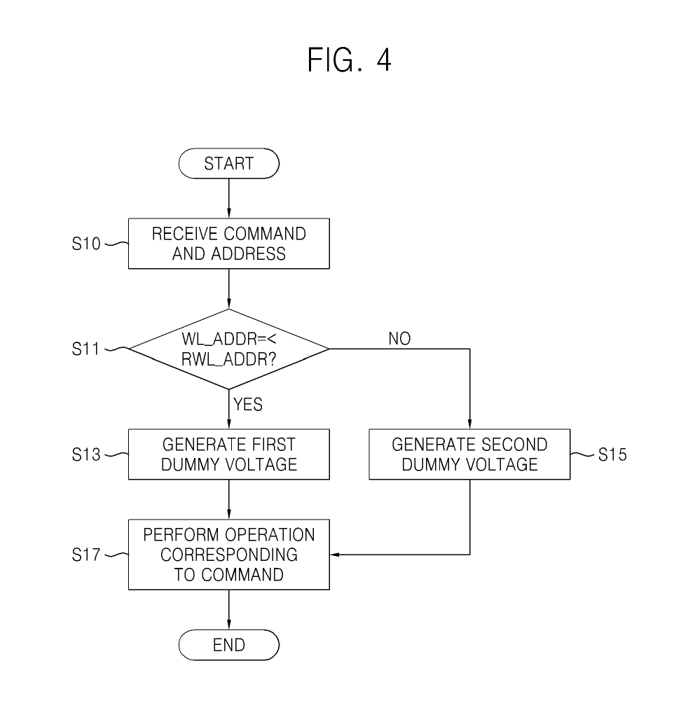

FIG. 4 is a flowchart summarizing one possible approach to controlling the operation of the non-volatile memory device 10 illustrated in FIG. 1. Referring collectively to FIGS. 1 through 4, the non-volatile memory device 10 receives an externally provided command CMD and a corresponding input address ADD, as needed (S10). The command CMD and address ADD may be received from a number of different kinds of sources, including but not limited to, a memory controller or host connected to the non-volatile memory device 10 via one or more channels. The one or more channels may be hardwired or wirelessly implemented. Although not specifically identified in FIG. 4, other data (e.g., write data) may also be received as part of the command CMD provided to the non-volatile memory device 10.

A word line address WL_ADDR may be selected (or derived) from the input address ADD and then compared with the one or more reference address(es) RWL_ADDR (S11). As described above, the reference address RWL_ADDR may be stored in a hardwired register or data storage unit, for example.

When the selected word line address WL_ADDR is less than or equal to a reference address RWL_ADDR, a first dummy word line voltage is generated (S13), otherwise a second dummy word line voltage is generated (S15). When the selected word line address WL_ADDR is less than or equal to a reference address RWL_ADDR, the selected word line (i.e., the word line selected by the address WL_ADDR) is adjacent to a dummy word line.

Alternatively, when the selected word line address WL_ADDR is greater than or equal to a reference address RWL_ADDR, the first dummy word line voltage is generated (S13), otherwise the second dummy word line voltage is generated (S15). That is, when the selected word line address WL_ADDR is less than or equal to a first reference address or greater than or equal to a second reference address, the first dummy word line voltage may be generated (S13), otherwise the second dummy word line voltage is generated (S15). Hence, as described above, various methods of determining whether a selected word line address WL_ADDR indicates that a selected word line is adjacent to a dummy word line may be used to define and generate an appropriate dummy word line voltage.

The first dummy word line voltage and the second dummy word line voltage will be “different” one from the other. This difference may be in at least one of level, waveform, application timing, etc. In order to selectively generate different dummy word line voltages, different first and second codes may be stored, wherein either of one of the first and second codes may be selected in response to a selection signal, and a corresponding dummy word line voltage generated. The selection signal may be generated by comparing the selected word line address WL_ADDR with the reference address RWL_ADDR, as described above.

Once a dummy word line voltage is appropriately defined, the dummy word line voltage is applied to the dummy word line during the operation indicated by the command CMD (S17).

Thus, according to embodiments of the present inventive concept, at least one characteristic (e.g., level, waveform, timing, etc.) of a dummy word line voltage applied to a dummy word line during an operation will be determined in accordance with the relative disposition of a selected word line and the dummy word line within a plurality of word lines. As a result, the frequency (or likelihood) of memory cell disturbances that might otherwise arise is reduced for memory cells adjacent to the dummy word line, the corresponding decrease in read margin due to such disturbances may be markedly suppressed.

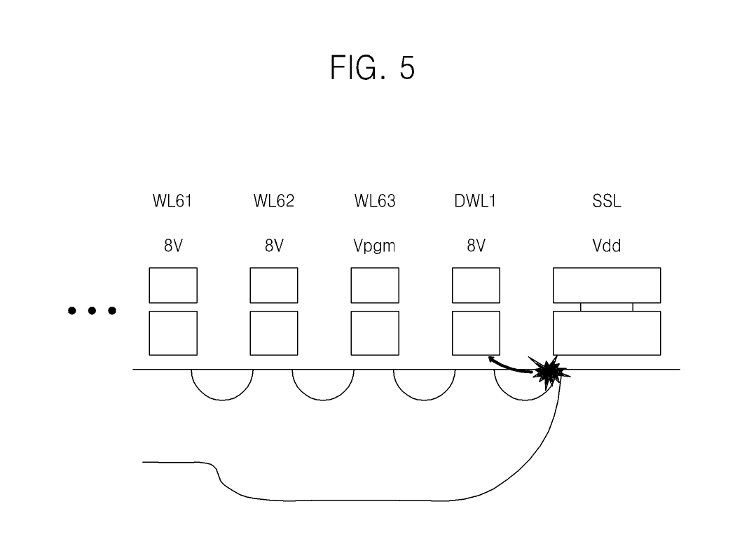

A comparison of the examples illustrated in FIGS. 5, 6 and 7 will further illuminate aspects of the inventive concept, using particular, assumed examples. FIG. 5 illustrates a portion of a string of memory cells (i.e., memory cells respectively connected to word line 61 (WL61), word line 62 (WL62), word line 63 (WL63)) and a dummy memory cell connected to a dummy word line (DWL1). It is assumed that the memory cells in FIG. 5 are subjected to conventionally generated control signals during a typical program operation. During the program operation, it is further assumed that word line 63 (WL63) is a selected word line receiving a program voltage (Vpgm), and is adjacent to the dummy word line (DWL1). Consistent with conventional practice, the program voltage (Vpgm) applied to the selected word line is a high voltage, while non-selected word lines are program-inhibited.

In the example of FIG. 5, the program-inhibit voltage applied to non-selected word lines (WL61 and WL62), including the dummy word line (DWL1), is assumed to be 8.0V. However, gate induced drain leakage (GIDL) easily occurs in relation to the program-inhibited bit line due to the difference between the relatively high channel voltage apparent at the dummy word line (DWL1) and the relatively low gate voltage of the string selection line SSL. Those skilled in the art will understand that the foregoing example of a 64^{th} word line (WL63) adjacent to a second dummy word line (DWL1) adjacent to a string selection line (SSL) may be extended to a similar example wherein a first word line (WL0) is adjacent to a first dummy word line (DWL0) adjacent to a ground selection line (GSL) and all line are similarly biased. (See, e.g., FIG. 2A). In either example, GIDL current generated during the program operation causes hot carrier injection (HCI), and as a result, a disturbance occurs between the second dummy word line (DWL1) and the 64th word line (WL63), or the first dummy word line (DWL0) and the 1st word line (WL0).

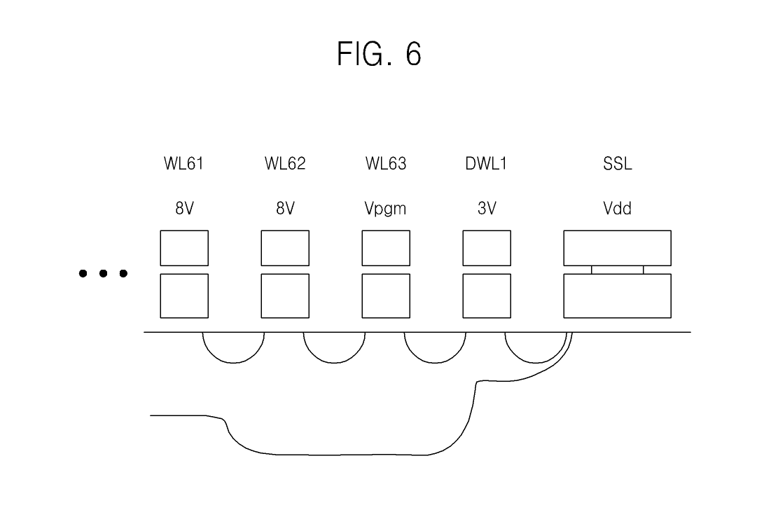

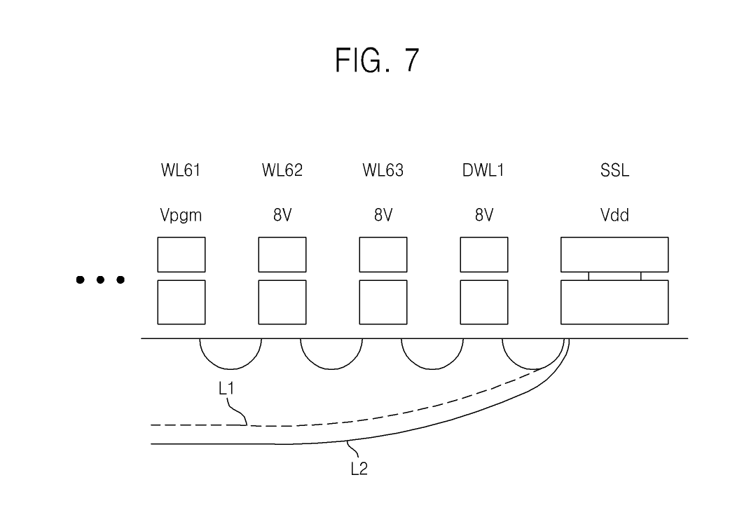

In contrast to the example illustrated in FIG. 5, the example illustrated in FIGS. 6 and 7 and consistent with embodiments of the inventive concept suppress GIDL current and preserve read margin. To accomplish these results among other desirable results, different dummy word line voltages are used upon determining whether a word line selected during a program operation is adjacent to a dummy word line. In the example illustrated in FIG. 6, the word line selected by the program operation is again adjacent to a dummy word line, whereas in the example illustrated in FIG. 7, the selected word line is not adjacent to the dummy word line.

Referring to FIG. 6, when the selected word line (WL63) is adjacent to the second dummy word line (DWL1), the dummy word line voltage applied to the second dummy word line (DWL1) is controlled such that it is less than the word line voltages applied to the non-selected word lines WL0 through WL62. More particularly, when the selected word line (WL63) is adjacent to the second dummy word line (DWL1) during a program operation, a voltage (e.g., 3.0 V) less than a pass voltage Vpass (e.g., 8.0 V) applied to the non-selected word lines WL0 through WL62 is applied to the second dummy word line (DWL1) to reduce or eliminate GIDL current and thereby reduce HCI.

Referring to FIG. 7, when the selected word line (here, WL61 instead of WL63) is not adjacent to the second dummy word line (DWL1), the dummy word line voltage applied to the second dummy word line (DWL1) may be the same (e.g., the same level) as the word line voltages applied to the non-selected word lines WL0 through WL60, WL62, and WL63. In other words, when the distance between a selected word line and a dummy word line increases, the ill-effects of GIDL and the resulting HCI decreases. Accordingly, the voltage applied to a dummy word line may be increased to facilitate high channel boosting efficiency. Consequently, the lesser voltage (e.g., 3.0 V in FIG. 6) applied to the second dummy word line (DWL1) when the selected word line is adjacent to the second dummy word line (DWL1) is less than the normal program-inhibit voltage (e.g., 8.0 V in FIG. 7) applied to the second dummy word line (DWL1) when the selected word line is not adjacent same. The foregoing comparative example illustrated how certain control voltages applied to a dummy word line may be defined and controlled, at least in part, on basis of a dispositional relationship between a selected word line and the dummy word line to thereby reduce or eliminate GIDL current and the resulting HCI and increase channel boosting efficiency.

At this point, it should be noted that embodiments of the inventive concept are limited to only a dispositional relationship wherein a selected word line is adjacent to a dummy word line. Other “proximate” dispositional relationships between a selected word line and a dummy word line may be used to vary the characteristic(s) of a control voltage applied to the dummy word line during an operation. For example, a non-adjacent, but proximate dispositional relationship (e.g., the selected word line is separated by less than 2 or less than 1 intervening word line from the dummy word line) may be used to control the definition of the dummy word line voltage.

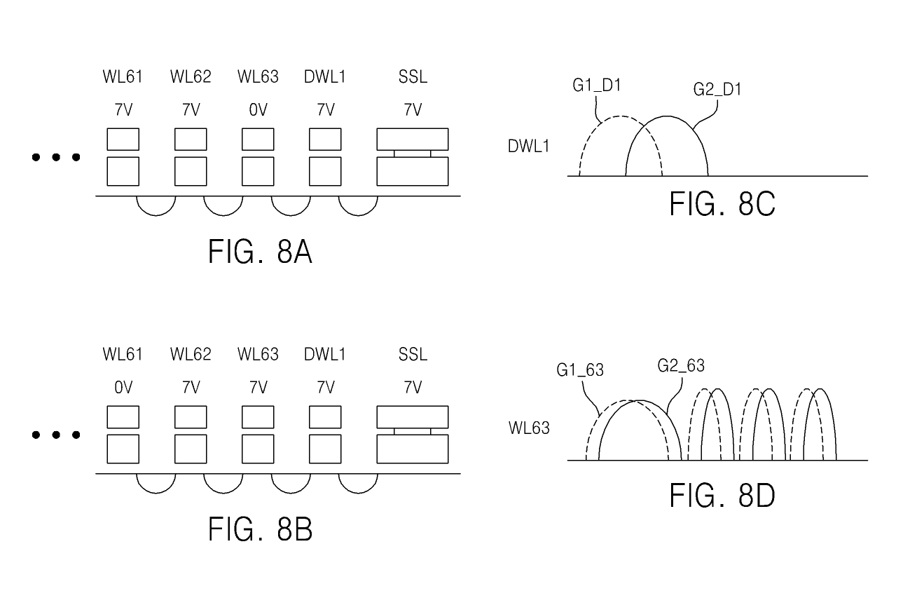

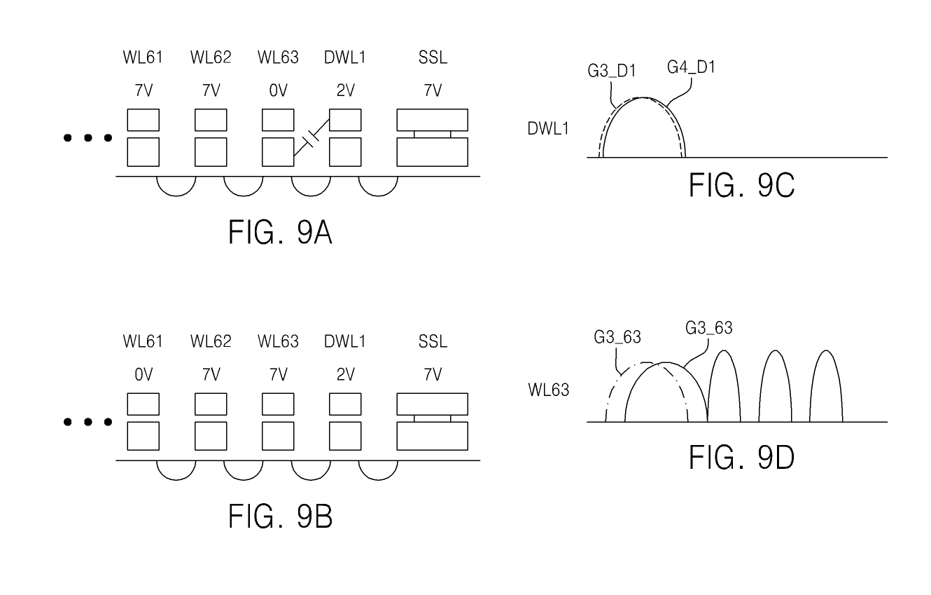

FIGS. 8A through 8D (collectively FIG. 8) and FIGS. 9A through 9D (collectively FIG. 9) are diagrams further illustrating the definition and provision of a dummy word line voltage during a typical read operation. Again, a portion of an assumed arrangement of word lines is illustrated under various bias conditions in FIGS. 8 and 9. FIG. 8 illustrate a case wherein conventional bias conditions are used in conjunction with a read operation, and the voltage applied to the dummy word line (DWL1) does not vary in relation to the relative disposition of a selected word line. (Compare FIG. 8A wherein WL63 adjacent to the dummy word line (DWL1) is selected with FIG. 8C wherein WL61 non-adjacent to the dummy word line (DWL1) is selected during the read operation).

When the voltage applied to the dummy word line (DWL1) is similar (e.g., about 7.0 V) to the voltage applied to non-selected word lines, as shown in FIG. 8A, the threshold voltage distribution of memory cells having an erase state shifts from an initial distribution (G1_D1) to a modified distribution (G2_D1), as illustrated in FIG. 8C. This unintended shift in threshold voltage distribution is due to the fact that the dummy word line DWL1 has been disturbed as a result of the relatively high voltage (around 7.0 V) applied during the read operation. That is, the threshold voltage distribution shift of the memory cell connected to the dummy word line (DWL1) leads to a coupling effect between the 64th word line (WL63) and the adjacent dummy word line (DWL1). As a result, the threshold voltage distribution of memory cells connected to the 64th word line (WL63) are changed, thereby reducing the read margin for such cells, as illustrated in FIG. 8C.

According to FIG. 9, to improve the read margin for memory cells connected to the 64th word line (WL63) adjacent to the dummy word line DWL1 the dummy word line voltage applied to the dummy word line (DWL1) may be reduced to be less than the voltage applied to the non-selected word lines but greater than the voltage applied to the selected word line, regardless of the dispositional relationship between the selected word line (either WL63 or WL61) and the dummy word line (DWL1). (Compare, FIG. 9A with FIG. 8A, noting the reduced disturbance of the threshold voltage distribution G3_D1 to the threshold voltage distribution G4_D1 shown in FIG. 9C as compared with FIG. 8C, and compare FIGS. 9B with 8B, noting the minimal disturbance of the threshold voltage distribution G3_63 to the threshold voltage distribution G4_63 shown in FIG. 9D as compared with FIG. 8D).

These results generally arise from the fact that the dummy word line voltage applied to the dummy word line (DWL1) is less than the voltage applied to the non-selected word lines. That is, when the voltage applied to the dummy word line (DWL1) during a read operation is less than the voltage applied to the non-selected word lines, the possibility of a disturbance in the dummy word line is reduced, so that the resulting shift in the threshold voltage distribution of memory cells connected to the dummy word line is small, as shown in FIG. 9C.

However, since a parasitic capacitance exists between the control gate of the dummy word line and the floating gate of adjacent word line(s), the potential of the floating gate decreases when the level of the read voltage applied to the dummy word line decreases. As a result, it is necessary to increase the voltage applied to the plurality of word lines WL0 and WL63 in order to turn ON the transistors of the memory cells connected to the plurality of word lines WL0 and WL63. In other words, when the selected word line WL63 (FIG. 9A) adjacent to the second dummy word line DWL1 is read, the voltage applied to the selected word line WL63 should be greater than the a read voltage applied to the second dummy word line DWL1. Consequently, when a read voltage applied to a dummy word line is reduced, the threshold voltage distribution for memory cell having the erased state and connected to adjacent word lines increases, so that the read margin between the erased state and an adjacent programmed state is decreased.

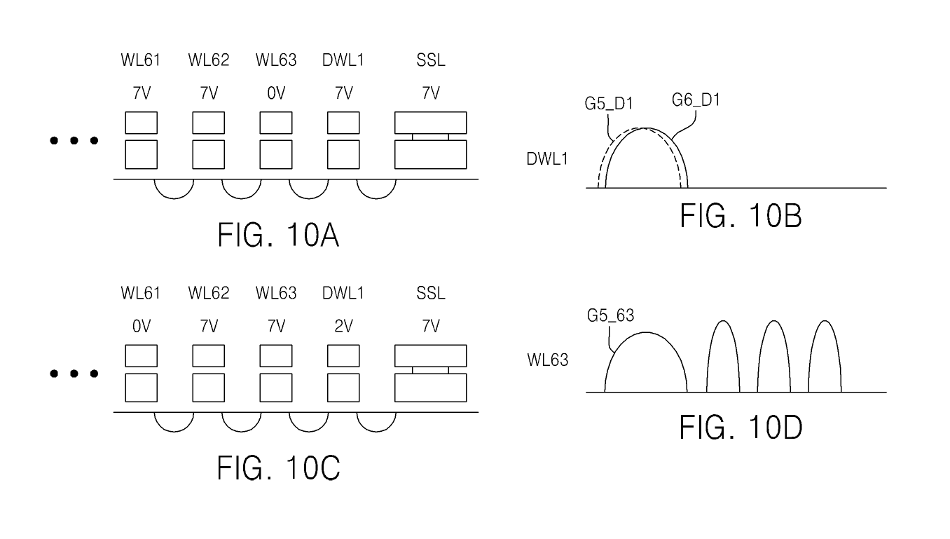

FIGS. 10A through 10D (collectively FIG. 10) are diagrams further illustrating certain aspects of the inventive concept in the context of a read operation and in relation to the dispositional relationship between a selected word line and a dummy word line. Referring to FIG. 10A, when the word line WL63 is selected during the read operation and the selected word line WL63 is adjacent to the second dummy word line DWL1, a read voltage for the second dummy word line DWL1 is increased so that the disturbing effect of the increase upon the threshold voltage distribution of memory cells having the erased state and connected to the word line WL63 is substantially eliminated, as illustrated in FIG. 10B. Referring to FIG. 10C, when the selected word line WL61 is not adjacent to the second dummy word line DWL1, the read voltage for the second dummy word line DWL1 may be decreased to a level less than the read voltage applied to non-selected word lines, but greater than the read voltage applied to the selected word line. In this manner, the likelihood of a read disturbance is markedly reduced or eliminated, as illustrated in FIG. 10D.

Thus, in conventional methods of operation, a high read voltage is always applied to the dummy word line during a read operation as shown in FIG. 8. Alternately, in other conventional methods of operation, a reduced read voltage may be applied to a dummy word line, regardless of the dispositional relationship of a selected word line as shown in FIG. 9. However, embodiments of the inventive concept take into account the dispositional relationship of a selected word line and dummy word lines in the non-volatile memory cell array, as shown in FIG. 10. Accordingly, the number of times a high read voltage (e.g., 7.0V) need be applied to certain non-volatile memory cells, per the example of FIG. 10, is about 1/64 (assuming a case of a base-64 string) of the number of times that the high read voltage need be applied in the cases illustrated in FIG. 8, so that the possibility of a read disturbance as well as memory cell wear is markedly decreased within embodiments of the inventive concept as compared with conventional approaches.

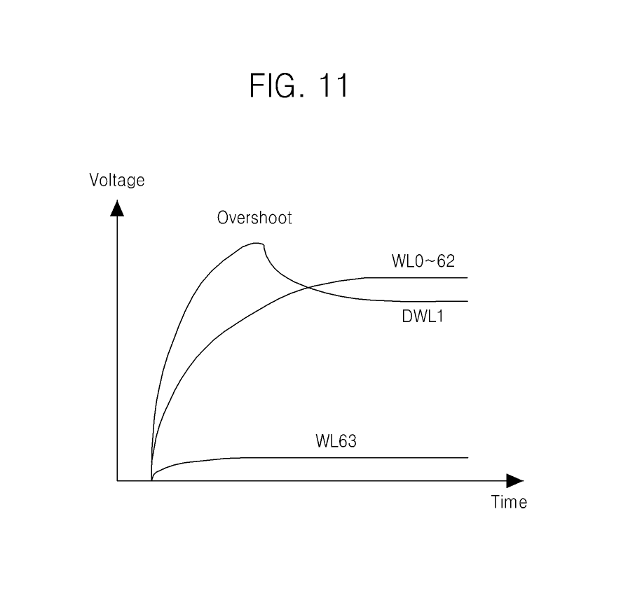

FIG. 11 is a voltage waveform diagram showing an overshoot that occurs in a typical dummy word line. Referring to FIG. 11, the dummy word line DWL1 has greater overshoot than the main word lines WL0 through WL62 may be due to a loading difference between the dummy word line DWL1 and the main word lines WL0 through WL62, or a driving difference in the performance of different drivers. Accordingly, when the selected word line WL63 is adjacent to the dummy word line DWL1 and the voltage level of the dummy word line DWL1 is high, the overshoot may lead to a disturbance.

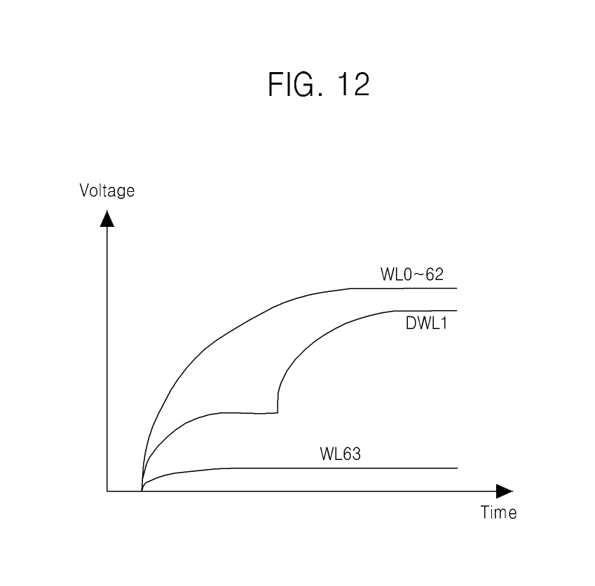

FIG. 12 is a voltage waveform diagram further illustrating a method of effectively changing the waveform of the voltage appearing on the dummy word line when the dispositional relationship of the selected word line is taken into account according to certain embodiments of the inventive concept. For example, when a word line WL63 adjacent to the dummy word line DWL1 is selected, the voltage applied to the dummy word line DWL1 may have a step waveform as shown in FIG. 12. That is, the voltage applied to the dummy word line DWL1 may have a low level initially and then after a predetermined time point it may have a higher level. Although not shown, instead of the voltage having the step waveform, a voltage similar to that applied to non-selected word lines may be applied to the dummy word line DWL1 when a word line that is not adjacent to the dummy word line DWL1 is selected.

As described above, when the waveform of the voltage applied to the dummy word line DWL1 is varied in accordance with the dispositional relationship of the selected word line, the overshoot occurring when a high voltage is applied to the dummy word line DWL1 can be prevented.

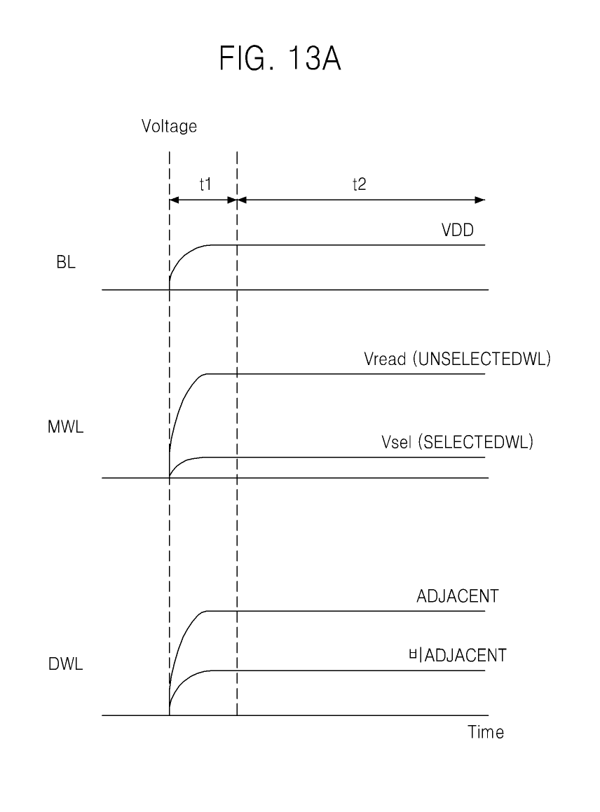

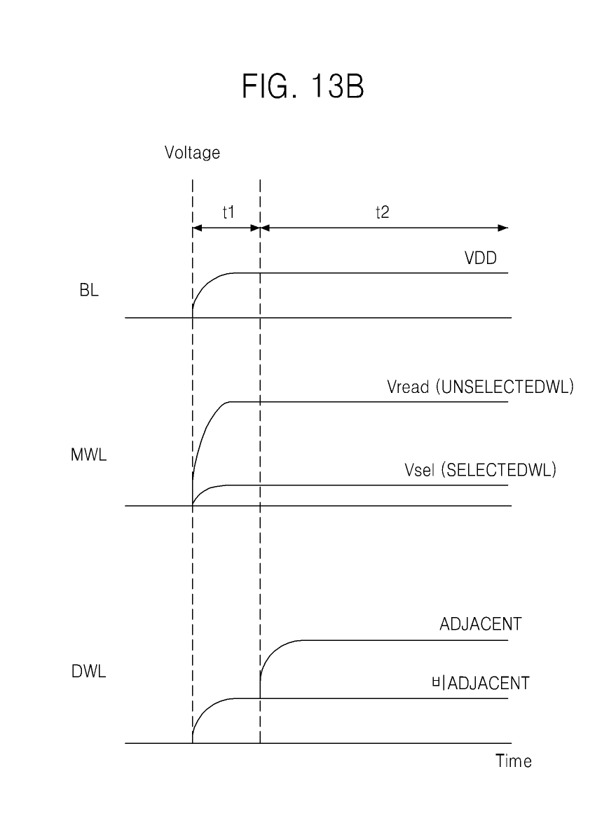

FIGS. 13A and 13B are a related collection of waveform diagrams that further illustrate a method of changing the level and/or waveform of a word line voltage applied to a dummy word line depending on the dispositional relationship of a selected word line during a read operation according to certain embodiments of the inventive concept. Referring to FIG. 13A, the level of a voltage applied to a dummy word line when a selected word line is adjacent to the dummy word line is greater than the level of a voltage applied to the dummy word line when the selected word line is not adjacent to the dummy word line. In other words, only the level of the voltage applied to the dummy word line is changed depending on whether the selected word line is adjacent to the dummy word line.

Referring to FIG. 13B, the voltage applied to the dummy word line has a step waveform when the selected word line is adjacent to the dummy word line and has a level less than a voltage applied to the selected word line when the selected word line is not adjacent to the dummy word line. In other words, both of the waveform and the level of the voltage applied to the dummy word line are changed depending on whether the selected word line is adjacent to the dummy word line.

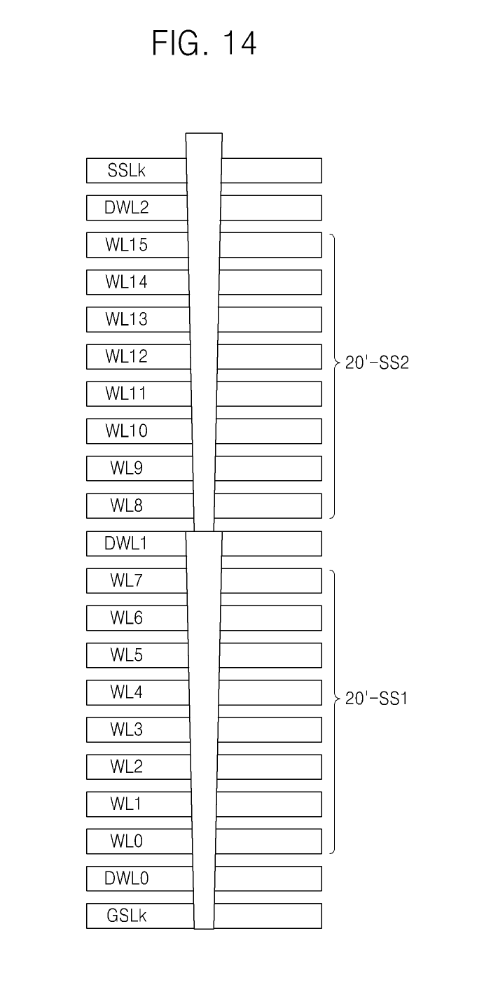

FIGS. 14 through 17 are related diagrams further illustrating a method of controlling the voltage applied to a dummy word line taking into account the dispositional relationship of a selected word line in a NAND flash memory device having a vertical memory cell array according an embodiment of the inventive concept. FIG. 14 is a partial cross section of the vertical memory array, and shows two (2) subsets of vertically stacked material layers (hereafter, a “vertical sub-stack”), each comprising an array of NAND flash memory cells. In the illustrated embodiment of FIG. 14, a first vertical sub-stack 20′-ss1 includes 1st through 8th word lines (WL0-WL7) bracketed between a 1st dummy word line (DWL0) and a 2nd dummy word line (DWL1), and a second vertical sub-stack 20′-ss2 includes 9th through 16th word lines (WL8-WL15) bracketed between the 2nd dummy word line (DWL1) and a 3rd dummy word line (DWL2). The combination of the 1st and 2nd sub-stacks is a vertical memory cell array bracketed between a lower ground selection line (GSLk) and an upper string selection line (SSLk).

In the foregoing configuration, the 2nd dummy line may be termed an “intermediate dummy word line” since it is disposed between adjacent ones of the plurality of main word lines within the vertical memory cell array. In contrast, each one of the 1st and 3^{rd} dummy word lines may be termed a “terminal dummy word line” since it is disposed at one end of the plurality of word lines. It should be noted that the embodiment shown in FIG. 14 includes only a single intermediate word line (DWL1) separating the 1st and 2nd sub-stacks. However, multiple intermediate dummy word lines may be used for this purpose or incorporated within a vertical memory cell array for different purposes. Similarly, more than one terminal dummy word line may be used at an upper or lower end of a vertical memory cell array.

Accordingly, each string of NAND flash memory cells in the vertical NAND memory cell array of FIG. 14 includes three (3) dummy word lines DWL0, DWL1, and DWL2.

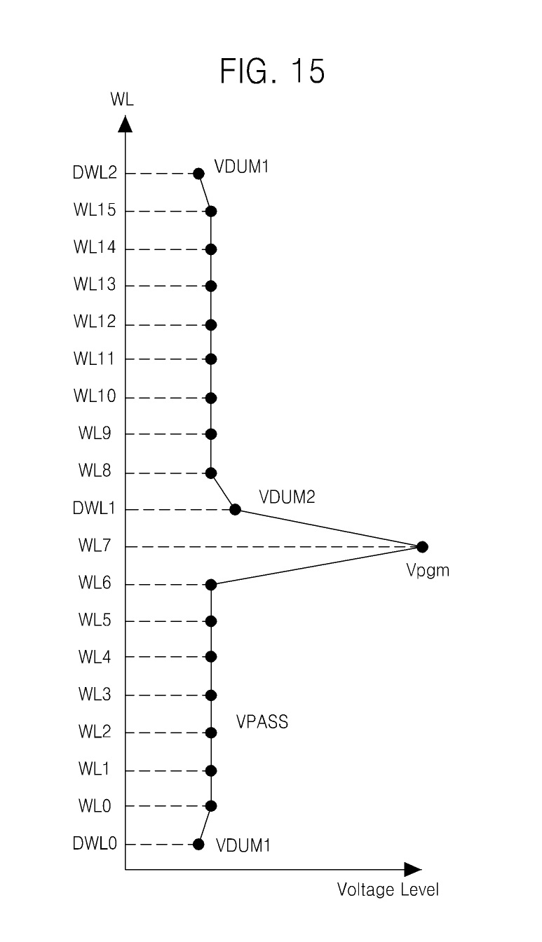

FIGS. 15, 16 and 17 illustrate in relation to the vertical memory cell array of FIG. 14 certain exemplary bias conditions that may exist according to certain embodiments of the inventive concept. Referring to FIG. 15 and assuming a program operation, when a selected word line WL7 is adjacent to the intermediate dummy word line DWL1, a second dummy word line voltage VDUM2 less than the voltage (Vpass) applied to the non-selected word lines is applied to the intermediate dummy word line DWL1. A first dummy word line voltage VDUM1 may be applied to the terminal dummy word lines DWL0 and DWL2 that is equal to Vpass.

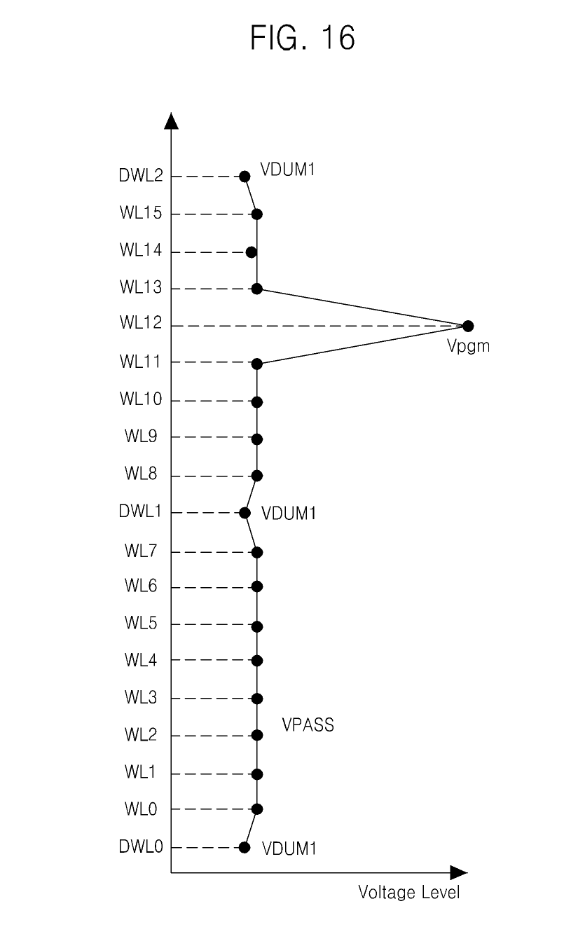

Referring to FIG. 16 and again assuming a program operation, when a selected word line WL12 is not adjacent to the intermediate dummy word line DWL1 (or either one of the terminal dummy word lines DWL0 and DWL2), the first dummy word line voltage VDUM1 may be applied to all of the dummy word lines.

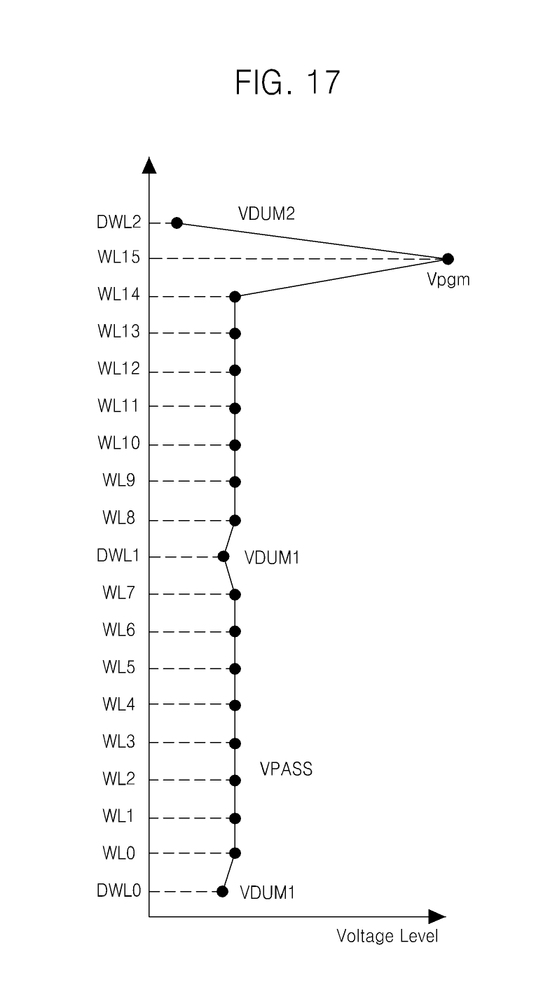

Referring to FIG. 17 and again assuming a program operation, when a selected word line WL15 is adjacent to the terminal dummy word line DWL2, the second dummy word line voltage VDUM2 less than Vpass is applied to the terminal dummy word line DWL2, and the first dummy word line voltage VDUM1 may be applied to the other terminal dummy word lines DWL0 and the intermediate dummy word line DWL1.

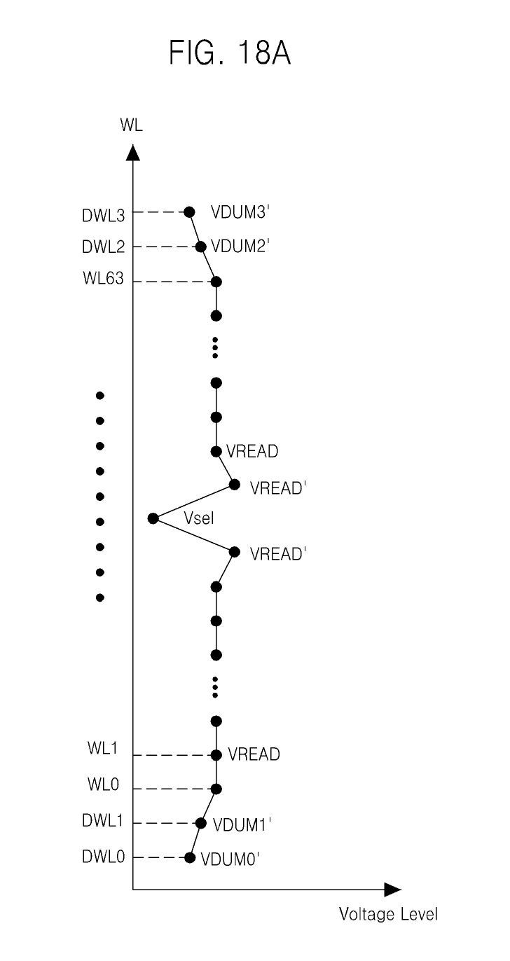

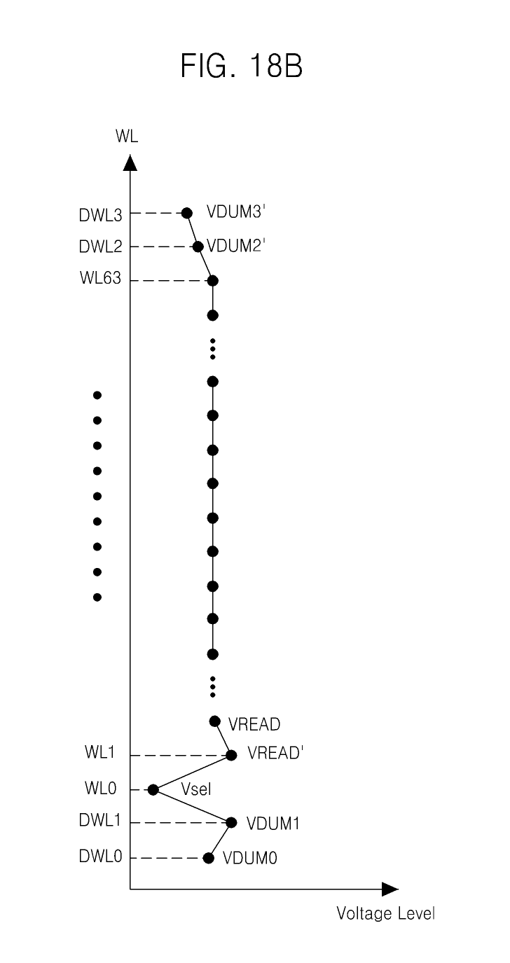

FIGS. 18A and 18B illustrate in relation to a vertical memory cell array different from the one shown in FIG. 14 exemplary bias conditions that may exist according to certain embodiments of the inventive concept. FIGS. 18A and 18B assume a vertical memory cell array including twin terminal dummy word lines (DWL0/DWL1 and DWL2/DWL3) bracketing a plurality of main word lines without an intermediate dummy line. Further, independent dummy word line voltage generators are assumed for each one of the dummy word lines.

Referring to FIG. 18A and assuming a read operation directed to a word line that is non-adjacent to a dummy word line, the NAND flash memory device is capable of generating four (4) distinct dummy word line voltages (VDUM0, VDUM1, VDUM2, and VDUM3). Of note, the first dummy word line voltage VDUM 0 and the second dummy word line voltage VDUM1 may be graduated relative to one another. That is, the first (or outer) dummy word line voltage VDUM0 may be slightly less than the second (or inner) dummy word line voltage VDUM1. The third and fourth dummy word line voltages may be similarly defined.

Further, the level of a read voltage (VREAD verses VREAD′) may be modified relative to the dispositional relationship of selected word line with word lines adjacent to the selected word line being slightly elevated, regardless of dispositional relationship to the twin sets of terminal dummy word lines.

The foregoing embodiments are selected examples of the inventive concept that intelligently adapt control voltages applied to (2D and 3D) memory cell arrays including one or more dummy word lines. Certain dispositional relationships (e.g., dispositional relationship(s) of the dummy word lines within a plurality of word lines, or dispositional relationship(s) between a dummy word line and a selected word line within the plurality of word lines) may be used to determine the applied characteristics (e.g., level, waveform, timing) of certain control voltages (e.g., read voltages, program voltages, erase voltages, dummy word line voltages, main word line voltages, bit line voltages) to a memory cell array. As a result, the incidence of disturbance in constituent memory cells may be markedly reduced. Consequently, a decrease in a read margin due to the disturbance can be suppressed, and furthermore, the operating characteristics of the non-volatile memory device can be improved.

So far, the illustrated embodiments have described non-volatile memory devices including flash memory devices, non-volatile memory cells arrays including both horizontal and vertical flash memory cell arrays, and methods of operating same. However, the scope of the inventive concept is not limited to only non-volatile memory cell arrays, memory devices and related methods of operation. Other embodiments of the inventive concept relate to systems incorporating such non-volatile memory devices including both horizontal and vertical flash memory cell arrays, and methods of operating same.

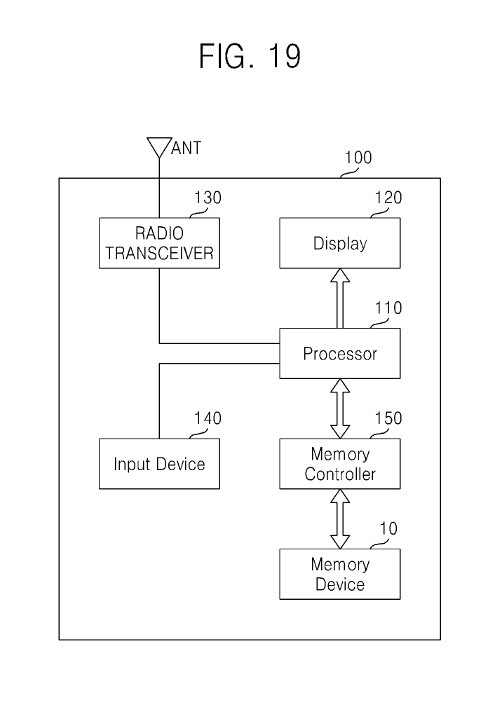

For example, FIG. 19 is a block diagram of a memory system 100 including the non-volatile memory device 10 of FIG. 1 according to an embodiment of the inventive concept. Referring to FIGS. 1 through 19, the memory system 100 may be implemented as a cellular phone, a smart phone, a tablet personal computer (PC), a personal digital assistant (PDA) or a radio communication system.

The memory system 100 includes the non-volatile memory device 10 and a memory controller 150 controlling the operations of the non-volatile memory device 10. The memory controller 150 may control the data access operations, e.g., a program operation, an erase operation, and a read operation, of the non-volatile memory device 10 according to the control of a processor 110.

The page data programmed in the non-volatile memory device 10 may be displayed through a display 120 according to the control of the processor 110 and/or the memory controller 150.

A radio transceiver 130 transmits or receives radio signals through an antenna ANT. The radio transceiver 130 may convert radio signals received through the antenna ANT into signals that can be processed by the processor 110. Accordingly, the processor 110 may process the signals output from the radio transceiver 130 and transmit the processed signals to the memory controller 150 or the display 120. The memory controller 150 may program the signals processed by the processor 110 to the non-volatile memory device 10. The radio transceiver 130 may also convert signals output from the processor 110 into radio signals and outputs the radio signals to an external device through the antenna ANT.

An input device 140 enables control signals for controlling the operation of the processor 110 or data to be processed by the processor 110 to be input to the memory system 100. The input device 140 may be implemented by a pointing device such as a touch pad or a computer mouse, a keypad, or a keyboard.

The processor 110 may control the operation of the display 120 to display data output from the memory controller 150, data output from the radio transceiver 130, or data output from the input device 140. The memory controller 150, which controls the operations of the non-volatile memory device 10, may be implemented as a part of the processor 110 or as a separate chip.

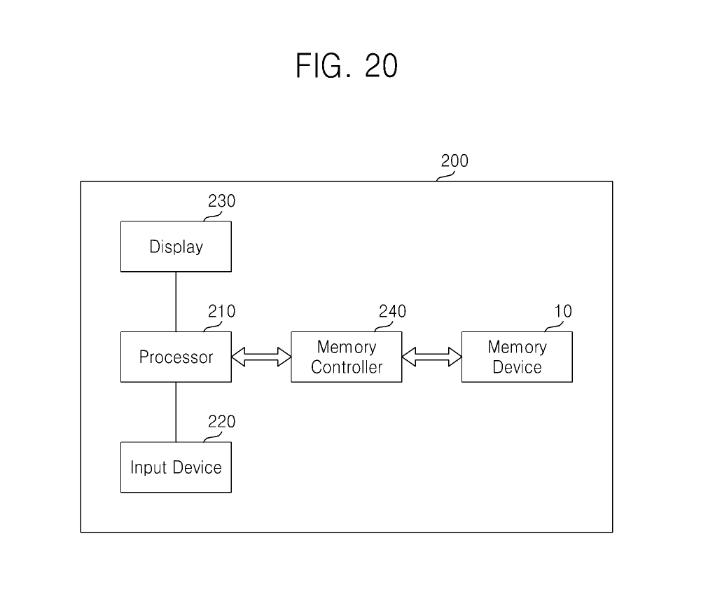

FIG. 20 is a block diagram of a memory system 200 including the non-volatile memory device 10 of FIG. 1 according to another embodiment of the inventive concept. The memory system 200 may be implemented as a PC, a tablet PC, a netbook, an e-reader, a PDA, a portable multimedia player (PMP), an MP3 player, or an MP4 player.

The memory system 200 includes the non-volatile memory device 10 and a memory controller 240 controlling the data processing operations of the non-volatile memory device 10. A processor 210 may display data stored in the non-volatile memory device 10 through a display 230 according to data input through an input device 220. The input device 220 may be implemented by a pointing device such as a touch pad or a computer mouse, a keypad, or a keyboard.

The processor 210 may control the overall operation of the memory system 200 and the operations of the memory controller 240. The memory controller 240, which may control the operations of the non-volatile memory device 10, may be implemented as a part of the processor 210 or as a separate chip.

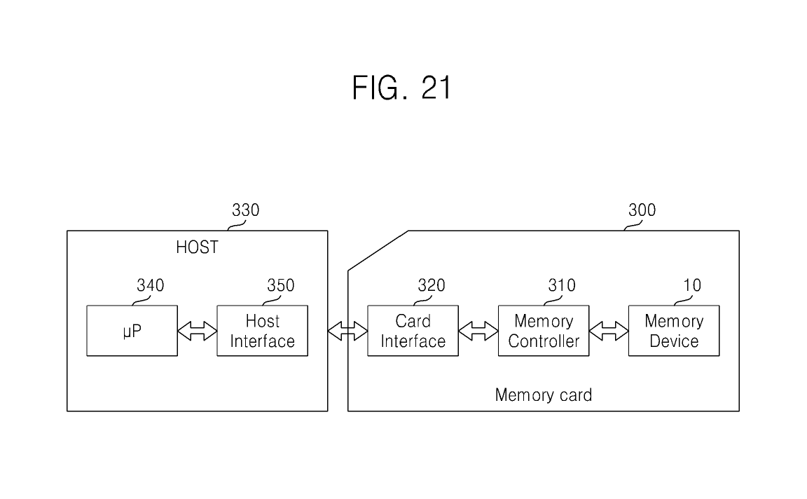

FIG. 21 is a block diagram of a memory system 300 including the non-volatile memory device 10 of FIG. 1 according to yet another embodiment of the inventive concept. The memory system 300 may be implemented as a memory card or a smart card. The memory system 300 includes the non-volatile memory device 10, a memory controller 310, and a card interface 320.

The memory controller 310 may control data exchange between the non-volatile memory device 10 and the card interface 320. The card interface 320 may be a secure digital (SD) card interface or a multi-media card (MMC) interface, but the present inventive concept is not restricted to the current embodiments.

The card interface 320 may interface a host 330 and the memory controller 310 for data exchange according to a protocol of the host 330. The card interface 320 may support a universal serial bus (USB) protocol and an inter-chip (IC)-USB protocol. Here, the card interface 320 may indicate a hardware supporting a protocol used by the host 330, a software installed in the hardware, or a signal transmission mode.

When the memory system 300 is connected with the host 330 such as a PC, a tablet PC, a digital camera, a digital audio player, a cellular phone, a console video game hardware, or a digital set-top box, a host interface 350 of the host 330 may perform data communication with the non-volatile memory device 10 through the card interface 320 and the memory controller 310 according to the control of a microprocessor 340.

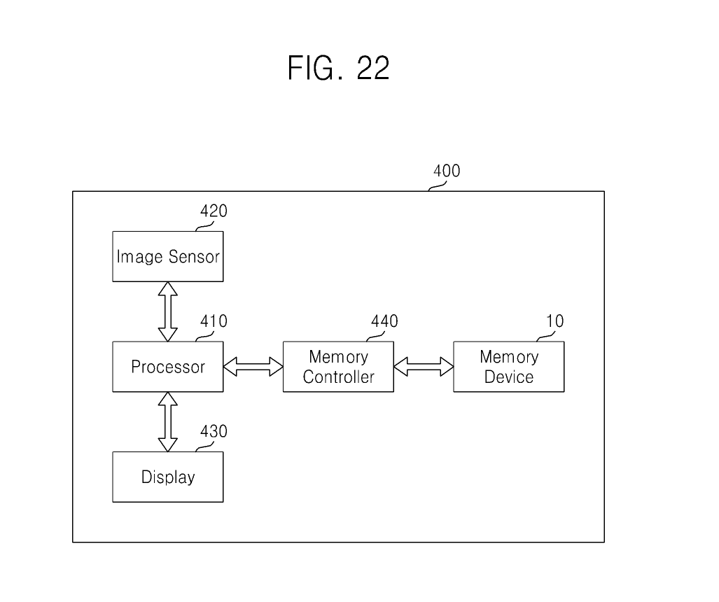

FIG. 22 is a block diagram of a memory system 400 including the non-volatile memory device 10 of FIG. 1 according to still another embodiment of the inventive concept. The memory system 400 may be implemented as an image processor like a digital camera, a cellular phone equipped with a digital camera, a smart phone equipped with a digital camera, or a tablet PC equipped with a digital camera.

The memory system 400 includes the non-volatile memory device 10 and a memory controller 440 controlling the data processing operations, such as a program operation, an erase operation, and a read operation, of the non-volatile memory device 10. An image sensor 420 included in the memory system 400 converts optical images into digital signals and outputs the digital signals to a processor 410 or the memory controller 440. The digital signals may be controlled by the processor 410 to be displayed through a display 430 or stored in the non-volatile memory device 10 through the memory controller 440.

Data stored in the non-volatile memory device 10 may be displayed through the display 430 according to the control of the processor 410 or the memory controller 440. The memory controller 440, which may control the operations of the non-volatile memory device 10, may be implemented as a part of the processor 410 or as a separate chip.

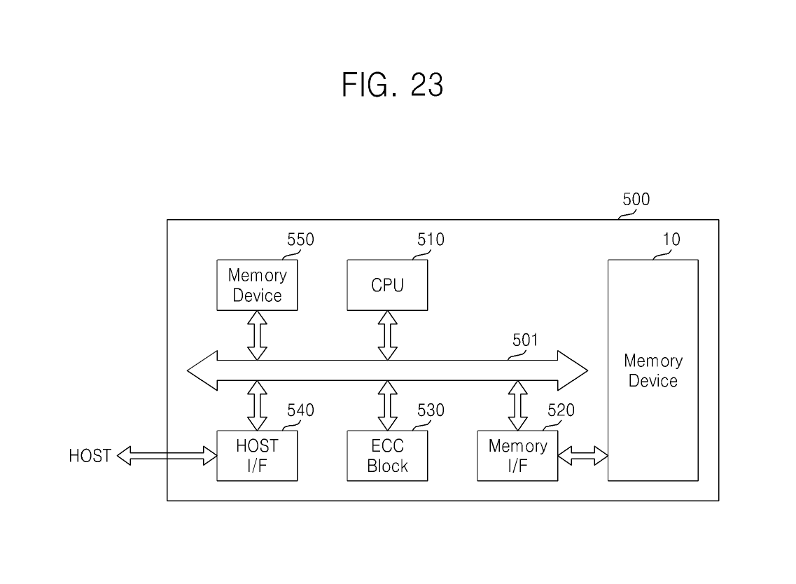

FIG. 23 is a block diagram of a memory system 500 including the non-volatile memory device 10 of FIG. 1 according to yet another embodiment of the inventive concept. The memory system 500 includes the non-volatile memory device 10 and a central processing unit (CPU) 510 controlling the operations of the non-volatile memory device 10.

The memory system 500 also includes a memory device 550 that my be used an operation memory of the CPU 510. The memory device 550 may be implemented by a non-volatile memory like read-only memory (ROM) or a volatile memory like static random access memory (SRAM). A host connected with the memory system 500 may perform data communication with the non-volatile memory device 10 through a memory interface 520 and a host interface 540.

An error correction code (ECC) block 530 is controlled by the CPU 510 to detect an error bit included in data output from the non-volatile memory device 10 through the memory interface 520, correct the error bit, and transmit the error-corrected data to the host through the host interface 540. The CPU 510 may control data communication among the memory interface 520, the ECC block 530, the host interface 540, and the memory device 550 through a bus 501. The memory system 500 may be implemented as a flash memory drive, a USB memory drive, an IC-USB memory drive, or a memory stick.

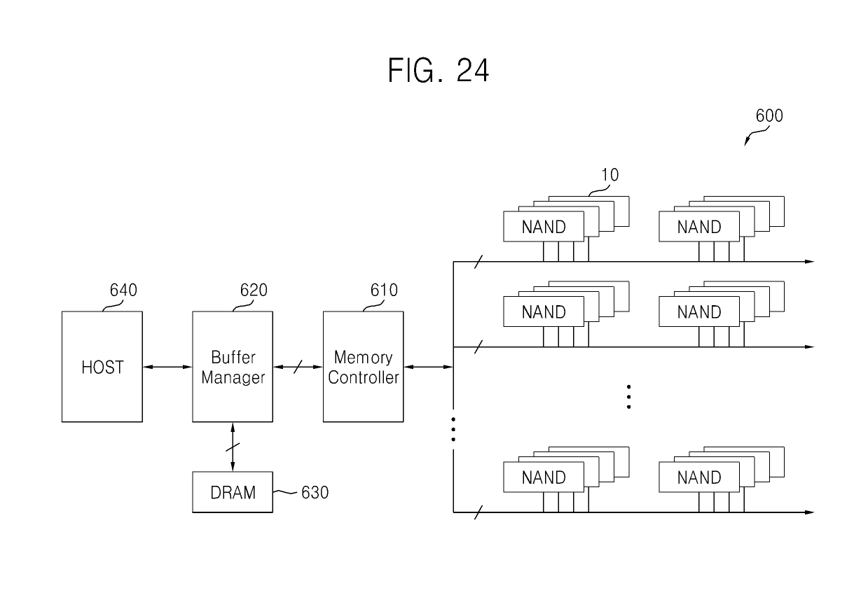

FIG. 24 is a block diagram of a memory system 600 including the non-volatile memory device 10 of FIG. 1 according to still another embodiment of the inventive concept. The memory system 600 may be implemented as a data storage system like a solid state drive (SSD).

The memory system 600 includes a plurality of non-volatile memory devices 10, a memory controller 610 controlling the data processing operations of the non-volatile memory devices 10, a volatile memory device 630 like a dynamic random access memory (DRAM), and a buffer manager 620 controlling data transferred between the memory controller 610 and a host 640 to be stored in the volatile memory device 630.

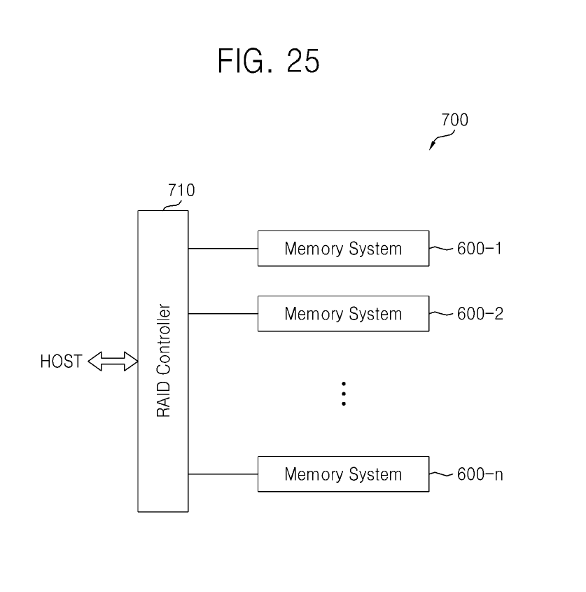

FIG. 25 is a block diagram of a data processor 700 including the memory system 600 of FIG. 24. Referring to FIGS. 24 and 25, the data processor 700 may be implemented as a redundant array of independent disks (RAID) system. The data processor 700 includes a RAID controller 710 and a plurality of memory systems 600-1 through 600-n, where “n” is a natural number.

Each of the memory systems 600-1 through 600-n may be the memory system 600 illustrated in FIG. 11. The memory systems 600-1 through 600-n may form a RAID array. The data processor 700 may be a PC or an SSD.

During a program operation, the RAID controller 710 may transmit program data output from a host to at least one of the memory systems 600-1 through 600-n according to a RAID level in response to a program command received from the host. During a read operation, the RAID controller 710 may transmit to the host data read from at least one of the memory systems 600-1 through 600-n in response to a read command received from the host.

While the present inventive concept has been particularly shown and described with reference to certain exemplary embodiments thereof, it will be understood by those of ordinary skill in the art that various changes in forms and details may be made therein without departing from the scope of the inventive concept as defined by the following claims.

What is claimed is:

1. A non-volatile memory device, comprising:
an array of nonvolatile memory cells arranged in relation to word lines including a dummy word line; and
access circuitry that selects during an operation a word line among the word lines in response to a received address, applies a selected word line voltage to the selected word line, applies a non-selected word line voltage to non-selected word lines among the word lines, and applies a dummy word line voltage to the dummy word line,
wherein the dummy word line voltage is a first dummy word line voltage when the selected word line is not adjacent to the dummy word line and a second dummy word line voltage different from the first dummy word line voltage when the selected word line is adjacent to the dummy word line.

2. The non-volatile memory device of claim 1, wherein the operation is a program operation and the first dummy word line voltage has a level greater than a level of the second dummy word line voltage.

3. The non-volatile memory device of claim 2, wherein the selected word line voltage is a program voltage, the non-selected word line voltage is a pass voltage having a level less than that of the program voltage, and the first dummy word line voltage is the pass voltage.

4. The non-volatile memory device of claim 1, wherein the operation is a read operation and the first dummy word line voltage has a level less than a level of the second dummy word line voltage.

5. The non-volatile memory device of claim 4, wherein the selected word line voltage is a first read voltage, the non-selected word line voltage is a second read voltage having a level greater than that of the first read voltage, the first dummy word line voltage is the second read voltage, and the second dummy word line has a level greater than that of the first read voltage and less than that of the second read voltage.

6. The non-volatile memory device of claim 1, wherein the nonvolatile memory cells are NAND flash memory cells further arranged in a NAND memory cell string, comprising:
a string selection transistor coupled to a string selection line;
a ground selection transistor coupled to a ground selection line;
a plurality of main NAND flash memory cells connected in series between the string selection transistor and the ground selection transistor, and respectively coupled to one of the word lines; and
a dummy NAND flash memory cell coupled to the dummy word line.

7. The non-volatile memory device of claim 5, wherein the dummy NAND flash memory cell is adjacent to the string selection transistor in the NAND memory string or the dummy NAND flash memory cell is adjacent to the ground selection transistor in the NAND memory string.

8. The non-volatile memory device of claim 1, wherein the access circuitry comprises:
control logic that receives the address and generates first and second control signals in response to the received address;
a voltage supply circuit configured to generate the selected word line voltage, the non-selected word line voltage, and at least one of the first dummy word line voltage and the second dummy word line voltage in response to the first control signal; and
a row decoder configured to apply the selected word line voltage to the selected word line, the non-selected word line voltage to the non-selected word lines, and the dummy word line voltage to the dummy word line in response to the second control signal.

9. The non-volatile memory device of claim 8, wherein the control logic comprises:
a comparator that compares a reference address associated with the dummy line with at least a portion of the received address to provide a comparison signal; and
a selector that provides the first control signal in response to the comparison signal.

10. The non-volatile memory device of claim 9, wherein the selector comprises:
a code selector that receives a first code associated with the first dummy word line voltage and a second code associated with the second dummy word line voltage, and selectively provides one of the first code and second code as the first control signal.

11. The non-volatile memory device of claim 8, wherein the voltage supply circuit comprises a first voltage level generator providing the first dummy word line voltage and a separate second voltage level generator providing the second dummy word line voltage.

12. The non-volatile memory device of claim 8, wherein the first dummy word line voltage has a waveform different from that of the second dummy word line voltage.

13. The non-volatile memory device of claim 8, wherein the first dummy word line voltage has a level different from that of the second dummy word line voltage.

14. A non-volatile memory device, comprising:
a vertical memory cell array including a plurality of non-volatile memory cells arranged in a plurality of memory cell array layers stacked in a first direction, and words lines that extend in a second direction across the plurality of memory cell array layers and include a dummy word line; and
access circuitry that selects during an operation a word line among the word lines in response to a received address, applies a selected word line voltage to the selected word line, applies a non-selected word line voltage to non-selected word lines among the word lines, and applies a dummy word line voltage to the dummy word line,
wherein the dummy word line voltage is a first dummy word line voltage when the selected word line is not adjacent to the dummy word line and a second dummy word line voltage when the selected word line is adjacent to the dummy word line.

15. The non-volatile memory device of claim 14, wherein at least one of; the first dummy word line voltage has a different waveform than that of the second dummy word line voltage, and
the first dummy word line voltage has a different level than that of the second dummy word line voltage.

16. The non-volatile memory device of claim 15, wherein each one of the plurality of nonvolatile memory cells is a NAND flash memory cell, and the plurality of nonvolatile memory cells is further arranged in a plurality of NAND memory cell strings, each one of the plurality of NAND flash memory strings extending from a lowest one of the plurality of memory cell array layers to a highest one of the plurality of memory cell array layers and comprising:
a string selection transistor coupled to a string selection line;
a ground selection transistor coupled to a ground selection line;
a plurality of main NAND flash memory cells connected in series between the string selection transistor and the ground selection transistor, and respectively coupled to one of the word lines; and
a dummy NAND flash memory cell coupled to the dummy word line.

17. The non-volatile memory device of claim 16, wherein the dummy NAND flash memory cell is adjacent to the string selection transistor in the NAND memory string.

18. The non-volatile memory device of claim 16, wherein the dummy NAND flash memory cell is adjacent to the ground selection transistor in the NAND memory string.

19. A non-volatile memory device, comprising:
a vertical memory cell array including a plurality of non-volatile memory cells arranged in a plurality of memory cell array layers stacked in a first direction, and words lines that extend in a second direction across the plurality of memory cell array layers and include a plurality of dummy word lines; and
access circuitry that selects during an operation a word line among the word lines in response to a received address, applies a selected word line voltage to the selected word line, applies a non-selected word line voltage to non-selected word lines among the word lines, and respectively applies one of a plurality of dummy word line voltages to each one of the plurality of dummy word lines, wherein the plurality of dummy word line voltages comprises;
a first dummy word line voltage applied to a respective dummy word line when the selected word line is not adjacent to the respective dummy word line, and
a second dummy word line voltage applied to the respective dummy word line when the selected word line is adjacent to the respective dummy word line.

20. The non-volatile memory device of claim 19, wherein at least one of; the first dummy word line voltage has a different waveform than that of the second dummy word line voltage, and the first dummy word line voltage has a different level than that of the second dummy word line voltage.

21. A non-volatile memory device, comprising:
a vertical memory cell array including a plurality of non-volatile memory cells arranged in a plurality of memory cell array layers stacked in a first direction, and words lines that extend in a second direction across the plurality of memory cell array layers and include a plurality of dummy word lines; and
access circuitry that selects during an operation a word line among the word lines in response to a received address, applies a selected word line voltage to the selected word line, applies a non-selected word line voltage to non-selected word lines among the word lines, and respectively applies one of a plurality of dummy word line voltages to each one of the plurality of dummy word lines, wherein the plurality of dummy word line voltages comprises a first dummy word line voltage applied to a respective dummy word line when the selected word line is not adjacent to the respective dummy word line, and a second dummy word line voltage applied to the respective dummy word line when the selected word line is adjacent to the respective dummy word line,
at least one of the first dummy word line voltage has a different waveform than that of the second dummy word line voltage, and the first dummy word line voltage has a different level than that of the second dummy word line voltage, and
the plurality of dummy word lines comprises at least one terminal dummy word line and at least one intermediate dummy word line;
each one of the plurality of nonvolatile memory cells is a NAND flash memory cell;
the plurality of nonvolatile memory cells is further arranged in a plurality of NAND memory cell strings that respectively extend in the first direction through the stacked plurality of memory cell layers, and each one of the plurality of NAND memory cell strings comprises;
a string selection transistor coupled to a string selection line;
a ground selection transistor coupled to a ground selection line;
a first set of NAND flash memory cells connected in series between the string selection transistor and the intermediate dummy word line and respectively coupled to a first set of the word lines; and
a second set of NAND flash memory cells connected in series between the intermediate dummy word line and the ground selection transistor, and respectively coupled to a second set of the word lines.

22. The non-volatile memory device of claim 21, wherein the first set of NAND flash memory cells comprises a first terminal dummy NAND flash memory cell adjacent to the string selection transistor and coupled to a first terminal dummy word line.

23. The non-volatile memory device of claim 22, wherein the second set of NAND flash memory cells comprises a second terminal dummy NAND flash memory cell adjacent to the ground selection transistor and coupled to a second terminal dummy word line.

24. The non-volatile memory device of claim 23, wherein the at least one intermediate dummy word line is disposed between the first terminal dummy word line and the second terminal dummy word line.

25. A system comprising:
a memory controller configured to control operation of a non-volatile memory device, wherein the non-volatile memory device comprises:
an array of nonvolatile memory cells arranged in relation to word lines including a dummy word line; and
access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

26. The system of claim 25, further comprising:
a processor configured to control operation of the memory controller; and
a display configured to display an image defined by output data retrieved from the non-volatile memory device by operation of the processor and the memory controller.

27. The system of claim 26, further comprising:
an image sensor configured to generate input data, wherein the processor and the memory controller operate to store the input data in the non-volatile memory.

28. The system of claim 26, further comprising:
an input device configured to provide input data, wherein the processor and the memory controller operate to store the input data in the non-volatile memory.

29. The system of claim 26, further comprising:
a transceiver configured to wirelessly receive a data signal and generate input data from the data signal, wherein the processor and the memory controller operate to store the input data in the non-volatile memory.

30. A memory card system, comprising:
an interface operatively connecting the memory card system with a host to receive input data from the host and communicate output data to the host;
a memory controller configured to receive the input data from the interface, store the input data in a non-volatile memory device, receive the output data from the nonvolatile memory device, and communicate the output data to the host,
wherein the non-volatile memory device comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

31. The memory card system of claim 30, wherein the interface, the memory controller and the nonvolatile memory device are collectively mounted on a board, and operated according to a data communication protocol compatible with the host.

32. A Solid State Drive (SSD), comprising:
a memory controller configured to control operation of a plurality of non-volatile memory devices via a plurality of channels, wherein each one of the plurality of non-volatile memory devices comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

33. The SSD of claim 32, further comprising:
a buffer manager interfacing the memory controller with a host; and
a volatile memory device configured with the buffer manager to communicate input data from the host to the memory controller, and communicate output data from the memory controller to the host.

34. A redundant array of independent disks (RAID) system, comprising:
a RAID controller connected to a plurality of memory systems via respective channels, wherein each one of the plurality of memory systems comprises a memory controller configured to control operation of a plurality of non-volatile memory devices, and
wherein each one of the plurality of non-volatile memory devices comprises; an array of nonvolatile memory cells arranged in relation to word lines including a dummy word line, and access circuitry that during an operation selects a word line among the word lines in response to a received address, applies a selected word line voltage to the selected word line, applies a non-selected word line voltage to non-selected word lines among the word lines, and applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.

35. A method of operating a nonvolatile memory device, comprising
receiving an address associated with an operation to be executed by the nonvolatile memory device; and
in response to the address, selecting a word line among word lines of the nonvolatile memory device, applying a selected word line voltage to the selected word line, applying a non-selected word line voltage to non-selected word lines among the word lines, and applying a dummy word line voltage to a dummy word line among the word lines, wherein the dummy word line voltage is a first dummy word line voltage when the selected word line is not adjacent to the dummy word line and a second dummy word line voltage different from the first dummy word line voltage when the selected word line is adjacent to the dummy word line.

36. The method of claim 35, wherein the first dummy word line voltage has a level greater than a level of the second dummy word line voltage.

37. The method of claim 36, wherein the operation is a program operation, the selected word line voltage is a program voltage, the non-selected word line voltage is a pass voltage having a level less than that of the program voltage, and the first dummy word line voltage is the pass voltage.

38. The method of claim 35, wherein the operation is a read operation, the selected word line voltage is a first read voltage, the non-selected word line voltage is a second read voltage having a level greater than that of the first read voltage, the first dummy word line voltage is the second read voltage, and the second dummy word line has a level greater than that of the first read voltage and less than that of the second read voltage.

39. The method of claim 35, wherein the nonvolatile memory device comprises a string selection transistor coupled to a string selection line, and a dummy memory cell adjacent to the string selection transistor and coupled to the dummy word line.

40. The method of claim 35, wherein the nonvolatile memory device comprises a ground selection transistor coupled to a ground selection line, and a dummy memory cell adjacent to the ground selection transistor and coupled to the dummy word line.

41. A method of operating a memory system comprising a memory controller and a nonvolatile memory device, the nonvolatile memory device including word lines and a dummy word line, and the method comprising:
communicating a command and an address from the memory controller to the nonvolatile memory device, wherein the address selects a word line among the word lines; and
determining whether the selected word line is adjacent to the dummy word line, and upon determining that the selected word line is adjacent to the dummy word line applying a first dummy word line voltage to the dummy word line, else applying a second dummy word line voltage different from the first dummy word line voltage to the dummy word line.

42. The method of claim 41, wherein the first dummy word line voltage has a level less than that of the second dummy word line voltage.

43. A non-volatile memory device, comprising:
an array of nonvolatile memory cells arranged in relation to word lines including a dummy word line; and
access circuitry that during an operation selects a word line among the word lines in response to a received address, applies a selected word line voltage to the selected word line, and applies a non-selected word line voltage to non-selected word lines among the word lines, wherein the access circuitry comprises dummy word line control logic that during the operation applies a dummy word line voltage to the dummy word line, wherein the dummy word line voltage is a first dummy word line voltage when the selected word line is not adjacent to the dummy word line and a second dummy word line voltage different from the first dummy word line voltage when the selected word line is adjacent to the dummy word line.
